(19) United States
(12) Patent Application Publication
(10) Pub. No.: US 2026/0076080 A1
(43) Pub. Date: Mar. 12, 2026

(54) LIGHT EMITTING DEVICE AND EYEWEAR DEVICE

(71) Applicant: SONY SEMICONDUCTOR SOLUTIONS CORPORATION, KANAGAWA (JP)

(72) Inventors: CHUGEN HAMACHI, KANAGAWA (JP); YOSUKE MOTOYAMA, KANAGAWA (JP)

(21) Appl. No.: 19/105,321

(22) PCT Filed: Aug. 29, 2023
(86) PCT No.: PCT/JP2023/031124

§ 371 Date: Feb. 20, 2025

(30) Foreign Application Priority Data
Aug. 30, 2022 (JP) 2022-137132

(51) Int. Cl. H10K 59/80; H10K 59/38

(52) U.S. Cl. CPC H10K 59/8792; H10K 59/38

(57) ABSTRACT

Provided is a light emitting device capable of suppressing reflection of near infrared rays. The light emitting device includes a near-infrared absorption layer. The near-infrared absorption layer is provided in the effective pixel region and a peripheral region located around the effective pixel region. The near-infrared absorption layer has a pattern portion in the effective pixel region.

### TECHNICAL FIELD

The present disclosure relates to a light emitting device and an eyewear device including the light emitting device.

### BACKGROUND ART

A light emitting device such as an organic light emitting diode (OLED) display device may include a functional layer that transmits light in a specific wavelength range. For example, Patent Document 1 discloses an organic EL device capable of reducing thermal deterioration of an organic light emitting layer by disposing a selective reflection film on the viewing side of an organic EL element and reflecting near infrared rays from the outside.

### CITATION LIST

### Patent Document

Patent Document 1: Japanese Patent Application Laid-Open No. 2010-232041

### SUMMARY OF THE INVENTION

### Problems to be Solved by the Invention

In recent years, it has been desired to suppress reflection of near infrared rays in a light emitting device. For example, in an eyewear device such as a head-mounted display (HMD), eye tracking or the like for specifying the position of a pupil using near infrared rays is mounted, and it is required to suppress near infrared rays reflected by a light emitting device as much as possible.

In Patent Document 1, only a technique for reflecting near infrared rays is studied, and a technique for suppressing reflection of near infrared rays is not studied.

An object of the present disclosure is to provide a light emitting device capable of suppressing reflection of near infrared rays and an eyewear device including the light emitting device.

### Solutions to Problems

In order to solve the above problem, a light emitting device according to the present disclosure includes:
a near-infrared absorption layer, in which
the near-infrared absorption layer is provided in an effective pixel region and a peripheral region located around the effective pixel region, and
the near-infrared absorption layer includes a pattern portion in the effective pixel region.

An eyewear device according to the present disclosure includes the light emitting device described above.

### BRIEF DESCRIPTION OF DRAWINGS

FIG. 1 is a plan view of a display device according to one embodiment.

FIG. 2 is an enlarged plan view illustrating a part of an effective pixel region.

FIG. 3 is a cross-sectional view taken along line III-III of FIG. 1.

FIG. 4 is a plan view of a color filter.

FIGS. 5A and 5B are plan views of a color filter and a near-infrared absorption layer, respectively.

FIGS. 6A and 6B are plan views of a color filter and a near-infrared absorption layer, respectively.

FIG. 7 is a diagram of an example of transmission spectra of a red filter portion, a green filter portion, a blue filter portion, and a near-infrared absorption layer.

FIG. 8 is a cross-sectional view of a display device according to Modification 1.

FIG. 9 is a cross-sectional view of a display device according to Modification 2.

FIG. 10 is a cross-sectional view of a display device according to Modification 3.

FIG. 11 is a cross-sectional view of a display device according to Modification 4.

FIG. 12 is a cross-sectional view of a display device according to Modification 5.

FIGS. 13A, 13B, and 13C are conceptual diagrams illustrating a relationship among a normal line LN passing through a center of a light emitting unit, a normal line LN′ passing through a center of a lens member, and a normal line LN″ passing through a center of a wavelength selection unit, respectively.

FIG. 14 is a conceptual diagram illustrating a relationship among the normal line LN passing through the center of the light emitting unit, the normal line LN′ passing through the center of the lens member, and the normal line LN″ passing through the center of the wavelength selection unit.

FIGS. 15A and 15B are conceptual diagrams illustrating a relationship among the normal line LN passing through the center of the light emitting unit, the normal line LN′ passing through the center of the lens member, and the normal line LN″ passing through the center of the wavelength selection unit, respectively.

FIG. 16 is a conceptual diagram illustrating a relationship among the normal line LN passing through the center of the light emitting unit, the normal line LN′ passing through the center of the lens member, and the normal line LN″ passing through the center of the wavelength selection unit.

FIG. 17A is a schematic cross-sectional view for explaining a first example of a resonator structure. FIG. 17B is a schematic cross-sectional view for explaining a second example of the resonator structure.

FIG. 18A is a schematic cross-sectional view for explaining a third example of the resonator structure. FIG. 18B is a schematic cross-sectional view for explaining a fourth example of the resonator structure.

FIG. 19A is a schematic cross-sectional view for explaining a fifth example of the resonator structure. FIG. 19B is a schematic cross-sectional view for explaining a sixth example of the resonator structure.

FIG. 20 is a schematic cross-sectional view for explaining a seventh example of the resonator structure.

FIG. 21A is a front view of a digital still camera. FIG. 21B is a rear view of a digital still camera.

FIG. 22 is a perspective view of a head-mounted display.

FIG. 23 is a configuration view of a head-mounted display.

FIG. 24 is a perspective view of a television device.

FIG. 25 is a perspective view of a see-through head-mounted display.

FIG. 26 is a perspective view of a smartphone.

FIG. 27A is a view illustrating an internal state of a vehicle from a rear side to a front side of the vehicle. FIG. 27B is a view illustrating an internal state of a vehicle as viewed from an oblique rear side to an oblique front side of the vehicle.

### MODE FOR CARRYING OUT THE INVENTION

An embodiment of the present disclosure will be described in the following order with reference to the drawings. Note that, in all the drawings of the following embodiments, the same or corresponding parts are denoted by the same reference numerals.
1 One Embodiment (Example of Display Device)
2 Example
3 Modifications
4 Relationship among Normal Lines Extending through Centers of Light Emitting Units, Lens Members, and Wavelength Selection Units
5 Example of Resonator Structure
6 Application Examples (Examples of Electronic Apparatus)

### 1 ONE EMBODIMENT

### [Configuration of Display Device 101]

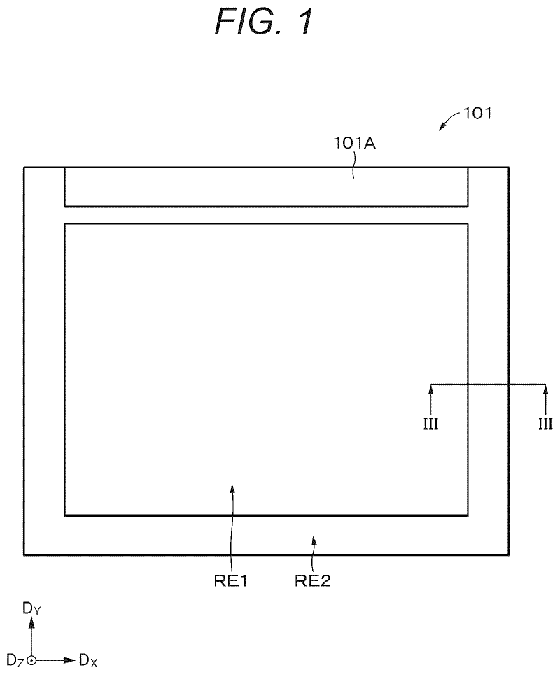

FIG. 1 is a plan view of a display device 101 according to one embodiment. The display device 101 includes an effective pixel region RE1 and a peripheral region RE2 provided around the effective pixel region RE1. In the present specification, the horizontal direction of the effective pixel region RE1 is referred to as a horizontal direction DX, and the vertical direction of the effective pixel region RE1 is referred to as a vertical direction DY. Furthermore, a direction perpendicular to the display surface of the display device 101 is referred to as a front direction DZ.

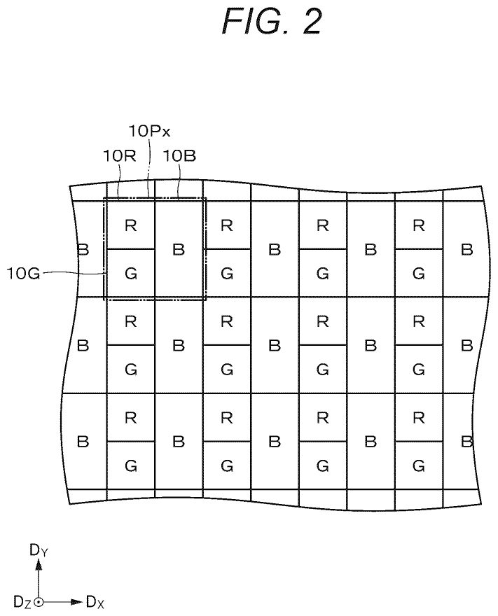

FIG. 2 is an enlarged plan view illustrating a part of the effective pixel region RE1. In FIG. 2, sections denoted by characters “R”, “G”, and “B” represent a sub-pixel (sub-pixel) 10R, a sub-pixel 10G, and a sub-pixel 10B, respectively. A plurality of sub-pixels 10R, 10G, and 10B is two-dimensionally arranged in a prescribed arrangement pattern in the effective pixel region RE1. In FIG. 2, the prescribed arrangement pattern is exemplified by a pixel array (also referred to as an S stripe array) in which a first column in which the sub-pixels 10R and the sub-pixels 10G are alternately arranged in the vertical direction DY and a second column in which only the sub-pixels 10B are alternately arranged in the vertical direction DY are alternately arranged in the horizontal direction DX. The prescribed arrangement pattern is not limited to the pixel array illustrated in FIG. 2, and may be a delta array, a stripe array, a square array, or an array other than these. A pad 101A, a video display driver (not illustrated), and the like are provided in the peripheral region RE2. A flexible printed circuit (FPC) (not illustrated) may be connected to the pad 101A.

The sub-pixels 10R can emit red light (first light). The sub-pixels 10G can emit green light (second light). The sub-pixels 10B can emit blue light (third light). In the following description, the sub-pixels 10R, 10G, and 10B are collectively referred to sub-pixels 10 in a case where they are collectively referred to without being particularly distinguished. One pixel (one pixel) 10Px is constituted by a plurality of adjacent sub-pixels 10R, 10G, and 10B.

The display device 101 is an example of a light emitting device. The display device 101 may be a top emission type OLED display device. The display device 101 may be a microdisplay. The display device 101 may be provided in an eyewear device such as a virtual reality (VR) device, a mixed reality (MR) device, an augmented reality (AR) device, an electronic view finder (EVF), a small projector, or the like.

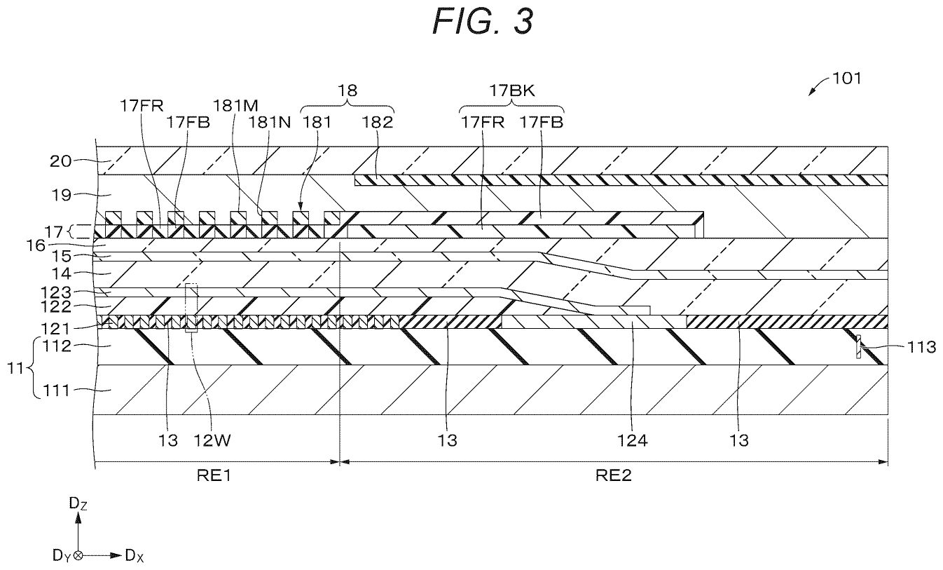

FIG. 3 is a cross-sectional view taken along line III-III of FIG. 1. The display device 101 includes a drive board 11, a plurality of light emitting elements 12W, a contact portion 124, an insulating layer 13, a protective layer (first protective layer) 14, a protective layer (second protective layer) 15, a planarization layer 16, a color filter 17, a light shielding layer 17BK, a near-infrared absorption layer 18, a protective layer 19, and a cover glass 20.

In the following description, a surface on the top side (display surface side) of the display device 101 is referred to as a first surface, and a surface on the bottom side (opposite side to the display surface) of the display device 101 is referred to as a second surface, in each layer constituting the display device 101.

### (Drive Board 11)

The drive board 11 is a so-called backplane and can drive a plurality of light emitting elements 12W. The drive board 11 includes, for example, a substrate 111 and an insulating layer 112 in order.

A plurality of drive circuits, a plurality of wirings (none of which are illustrated), and the like may be provided on the first surface of the substrate 111. The substrate 111 may include, for example, a semiconductor that is easy to form, such as a transistor, or may include glass or resin having low moisture and oxygen permeability. Specifically, the substrate 111 may be a semiconductor substrate, a glass substrate, a resin substrate, or the like. The semiconductor substrate contains amorphous silicon, polycrystalline silicon, monocrystalline silicon, or the like, for example. The glass substrate contains, for example, high strain point glass, soda glass, borosilicate glass, forsterite, lead glass, quartz glass, or the like. The resin substrate includes, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

The insulating layer 112 may be provided on the first surface of the substrate 111, and cover and planarize a plurality of drive circuits, a plurality of wirings, and the like. The insulating layer 112 insulates the plurality of drive circuits, the plurality of wirings, and the like provided on the first surface of the substrate 111 from the plurality of light emitting elements 12W. The insulating layer 112 may include a guard ring 113.

The insulating layer 112 may be an organic insulating layer, an inorganic insulating layer, or a multilayer body thereof. The organic insulating layer contains, for example, at least one selected from a group including a polyimide-based resin, an acrylic resin, a novolac-based resin, and the like. The inorganic insulating layer contains, for example, at least one selected from a group including silicon oxide (SiOx), silicon nitride (SiNx), silicon oxynitride (SiOxNy), and the like.

### (Light Emitting Element 12W)

The light emitting element 12W can emit white light under the control of a drive circuit or the like. The light emitting element 12W is an OLED element. The OLED element may be a micro-OLED (M-OLED) element. The light emitting element 12W is included in the sub-pixels 10R, 10G, and 10B.

The plurality of light emitting elements 12W is two-dimensionally arranged on the first surface of the drive board 11 in a prescribed arrangement pattern. The prescribed arrangement pattern is as described as the prescribed arrangement pattern of the plurality of sub-pixels 10. The light emitting element 12W includes a first electrode 121, an OLED layer 122, and a second electrode 123. The first electrode 121, the OLED layer 122, and the second electrode 123 are laminated on the first surface of the drive board 11.

### (First Electrode 121)

The first electrode 121 is provided on the second surface side of the OLED layer 122. The first electrode 121 is separately provided in the plurality of light emitting elements 12W in the effective pixel region RE1. That is, the first electrode 121 is divided between the light emitting elements 12W adjacent in the in-plane direction in the effective pixel region RE1. The first electrode 121 is an anode. When a voltage is applied between the first electrodes 121 and the second electrode 123, holes are injected from the first electrodes 121 into the OLED layer 122.

The first electrode 121 may be, for example, constituted by a metal layer or may be constituted by a metal layer and a transparent conductive oxide layer. In a case where the first electrode 121 is constituted by a metal layer and a transparent conductive oxide layer, the transparent conductive oxide layer is preferably provided on the OLED layer 122 side, from the viewpoint of allowing a layer having a high work function to adjoin the OLED layer 122.

The metal layer also has a function as a reflective layer that reflects light generated in the OLED layer 122. The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the above-described at least one metal element as a constituent element of an alloy. Specific examples of the alloy include an aluminum alloy and a silver alloy. Specific examples of the aluminum alloy include, for example, AlNd and AlCu.

A base layer (not illustrated) may be provided adjacent to the second surface side of the metal layer. The base layer is for improving crystal orientation properties of the metal layer during formation of the metal layer. The base layer contains, for example, at least one metal element selected from a group including titanium (Ti) and tantalum (Ta). The base layer may contain the above-described at least one metal element as a constituent element of an alloy.

The transparent conductive oxide layer contains a transparent conductive oxide. The transparent conductive oxide contains, for example, at least one selected from a group including an indium-containing transparent conductive oxide (hereinafter, referred to as an “indium-based transparent conductive oxide”), a tin-containing transparent conductive oxide (hereinafter, referred to as a “tin-based transparent conductive oxide”), and a zinc-containing transparent conductive oxide (hereinafter, referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among these transparent conductive oxides, indium tin oxide (ITO) is particularly preferable. This is because indium tin oxide (ITO) has a particularly low barrier for hole injection into the OLED layer 122 in terms of a work function, so that the drive voltage of the display device 101 can be particularly reduced. The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

### (OLED Layer 122)

The OLED layer 122 can emit white light. The OLED layer 122 is disposed between the first electrodes 121 and the second electrode 123. The OLED layer 122 is connected between adjacent light emitting elements 12W in an effective pixel region R1, and is shared by the plurality of light emitting elements 12W in the effective pixel region R1.

The OLED layer 122 may be an OLED layer including a single-layer light-emitting unit, may be an OLED layer including two layers of light-emitting units (tandem structure), or may be an OLED layer having another structure. The OLED layer including a single-layer light emitting unit has, for example, a configuration in which a hole injection layer, a hole transport layer, a red light emitting layer, a light emitting separation layer, a blue light emitting layer, a green light emitting layer, an electron transport layer, and an electron injection layer are stacked in this order from the first electrodes 121 toward the second electrode 123. The OLED layer including a two-layer light emitting unit has, for example, a configuration in which a hole injection layer, a hole transport layer, a blue light emitting layer, an electron transport layer, a charge generation layer, a hole transport layer, a yellow light emitting layer, an electron transport layer, and an electron injection layer are stacked in this order from the first electrodes 121 toward the second electrode 123.

The hole injection layer is for enhancing hole injection efficiency into each light emitting layer and suppressing leakage. The hole transport layer is for enhancing hole transport efficiency to each light emitting layer. The electron injection layer is for enhancing electron injection efficiency into each light emitting layer. The electron transport layer is for enhancing electron transport efficiency to each light emitting layer. The light emitting separation layer is a layer for adjusting injection of carriers into each light emitting layer, and light emitting balance of each color is adjusted by injecting electrons or holes into each light emitting layer via the light emitting separation layer. The charge generation layer supplies electrons and holes to two light emitting layers sandwiching the charge generation layer.

In response to application with an electric field to each of the red light emitting layer, the green light emitting layer, the blue light emitting layer, and the yellow light emitting layer, recombination occurs between holes injected from the first electrode 121 or the charge generation layer and electrons injected from the second electrode 123 or the charge generation layer, and red light, green light, blue light, and yellow light are emitted.

### (Second Electrode 123)

The second electrode 123 is provided on the first surface side of the OLED layer 122. The second electrode 123 is connected between adjacent light emitting elements 12W in an effective pixel region R1, and is shared by the plurality of light emitting elements 12W in the effective pixel region R1. The second electrode 123 is a cathode. When a voltage is applied between the first electrodes 121 and the second electrode 123, holes are injected from the second electrode 123 into the OLED layer 122. The second electrode 123 has translucency with respect to each light emitted from the OLED layer 122. The second electrode 123 is preferably a transparent electrode having transparency to visible light. In the present specification, visible light refers to light in a wavelength range of 360 nm or more and 830 nm.

The second electrode 123 preferably is constituted by a material having as high translucency as possible and a small work function in order to enhance luminous efficiency. The second electrode 123 is constituted by, for example, at least one layer of a metal layer or a transparent conductive oxide layer. More specifically, the second electrode 123 is constituted by a single layer film of a metal layer or a transparent conductive oxide layer or by a laminated film of a metal layer and a transparent conductive oxide layer. In a case where the second electrode 123 is constituted by a laminated film, the metal layer may be provided on the OLED layer 122 side, or the transparent conductive oxide layer may be provided on the OLED layer 122 side, but from the viewpoint of allowing a layer having a low work function to adjoin the OLED layer 122, the metal layer is preferably provided on the OLED layer 122 side.

The metal layer contains, for example, at least one metal element selected from a group including magnesium (Mg), aluminum (Al), silver (Ag), calcium (Ca), and sodium (Na). The metal layer may contain the above-described at least one metal element as a constituent element of an alloy. A specific example of the alloy includes an MgAg alloy, an MgAl alloy, an AlLi alloy, or the like. The transparent conductive oxide layer contains a transparent conductive oxide. As the transparent conductive oxide, a material similar to the transparent conductive oxide of the first electrode 121 described above can be exemplified.

### (Contact Portion 124)

The contact portion 124 is provided on the first surface of the drive board 11 in the peripheral region RE2. The contact portion 124 is an auxiliary electrode that connects the second electrode 123 to a base wiring and the like (not illustrated).

The first surface of the contact portion 124 is electrically connected to a peripheral edge portion of the second surface of the second electrode 123. On the other hand, the second surface of the contact portion 124 is connected to the base wiring and the like via the plurality of contact plugs and the like. In the present specification, the peripheral edge portion of the second surface refers to a region having a predetermined width from the peripheral edge of the second surface toward the inside.

The contact portion 124 may have a closed loop shape surrounding the entire outer periphery of the effective pixel region RE1 in plan view, or may have a partially divided loop shape partially surrounding the outer periphery of the effective pixel region RE1. In the present specification, a plan view means a plan view when an object is viewed from the front direction DZ.

The contact portion 124 is constituted by, for example, at least one of a metal layer or a metal oxide layer. More specifically, the contact portion 124 is constituted by, for example, a single layer film of a metal layer or a metal oxide layer, or a laminated film of the metal layer and the metal oxide layer. The contact portion 124 is preferably similar in configuration to the first electrode 121. In this case, since the contact portion 124 can be formed simultaneously with the first electrode 121, the process of manufacturing the display device 101 can be simplified.

As a constituent material of the contact portion 124, a material similar to the material of the first electrode 121 can be exemplified. Specifically, as constituent materials of the metal layer and the metal oxide layer of the contact portion 124, materials similar to the materials of the metal layer and the metal oxide layer of the first electrode 121 can be exemplified, respectively.

### (Insulating Layer 13)

The insulating layer 13 is provided in a portion between the separated first electrodes 121 on the first surface of the drive board 11. The insulating layer 13 insulates between the adjacent first electrodes 121. The insulating layer 13 has a plurality of openings. Each of the plurality of openings is provided for a corresponding one of light emitting elements 12W. More specifically, each of the plurality of openings is provided on the first surface (surface on the OLED layer 122 side) of each of the first electrodes 121. The first electrodes 121 and the OLED layer 122 are in contact with each other via the openings.

The insulating layer 13 may also be provided between the first electrode 121 and the contact portion 124 in the first surface of the drive board 11. The insulating layer 13 may insulate the first electrode 121 from the contact portion 124.

The insulating layer 13 may also be provided on a portion outside the contact portion 124 in the first surface of the drive board 11.

The insulating layer 13 may be an organic insulating layer, an inorganic insulating layer, or a multilayer body including these. The organic insulating layer contains, for example, at least one selected from a group including a polyimide-based resin, an acrylic resin, a novolac-based resin, and the like. The inorganic insulating layer contains, for example, at least one selected from a group including silicon oxide (SiOx), silicon nitride (SiNx), silicon oxynitride (SiOxNy), and the like.

### (Protective Layer 14)

The protective layer 14 is provided on the first surface of the drive board 11 so as to cover the plurality of light emitting elements 12W. The protective layer 14 has translucency with respect to light emitted from the light emitting element 12W. The protective layer 14 preferably has transparency to visible light. The protective layer 14 can protect the plurality of light emitting elements 12W and the like. The protective layer 14 shields the light emitting elements 12W from outside air and inhibits infiltration of moisture into the light emitting elements 12W from an external environment. Furthermore, in a case where the second electrode 123 is constituted by a metal layer, the protective layer 14 may have a function of suppressing oxidation of this metal layer.

The protective layer 14 contains, for example, an inorganic material or a polymer resin each having low hygroscopicity. The protective layer 14 may have a single layer structure or a multilayer structure. In a case where the thickness of the protective layer 14 is increased, a multilayer structure is preferable. This is for alleviating an internal stress in the protective layer 14. The inorganic material contains, for example, at least one selected from a group including silicon oxide (SiOx), silicon nitride (SiNx), silicon oxynitride (SiOxNy), titanium oxide (TiOx), aluminum oxide (AlOx), and the like. The polymer resin contains, for example, at least one selected from a group including a thermosetting resin, an ultraviolet curable resin, and the like. Specifically, the polymer resin includes, for example, at least one selected from a group including an acrylic resin, a polyimide resin, a novolac resin, an epoxy resin, a norbornene resin, a parylene-based resin, and the like.

### (Protective Layer 15)

The protective layer 15 is provided on the first surface of the protective layer 14. The protective layer 15 has translucency with respect to light emitted from the light emitting element 12W. The protective layer 15 preferably has transparency to visible light. The protective layer 15 can protect the plurality of light emitting elements 12W and the like. The protective layer 15 shields the light emitting elements 12W from outside air and inhibits infiltration of moisture into the light emitting elements 12W from an external environment.

The protective layer 15 contains, for example, a metal oxide. The protective layer 15 preferably is constituted by a deposit of a monolayer. More specifically, the protective layer 15 is preferably an atomic layer deposition (ALD) layer. When the protective layer 15 is constituted by a deposit of a monolayer, the effect of suppressing infiltration of moisture by the protective layer 15 can be improved. The protective layer 15 contains, for example, aluminum oxide (AlOx) or titanium oxide (TiOx).

### (Planarization Layer 16)

The planarization layer 16 covers the first surface of the protective layer 15 and forms a flat surface above the first surface of the protective layer 15. The planarization layer 16 includes, for example, an inorganic material or a polymer resin. As the inorganic material, a material similar to the inorganic material of the protective layer 14 can be exemplified. As the polymer resin, a material similar to the polymer resin of the protective layer 14 can be exemplified.

### (Color Filter 17)

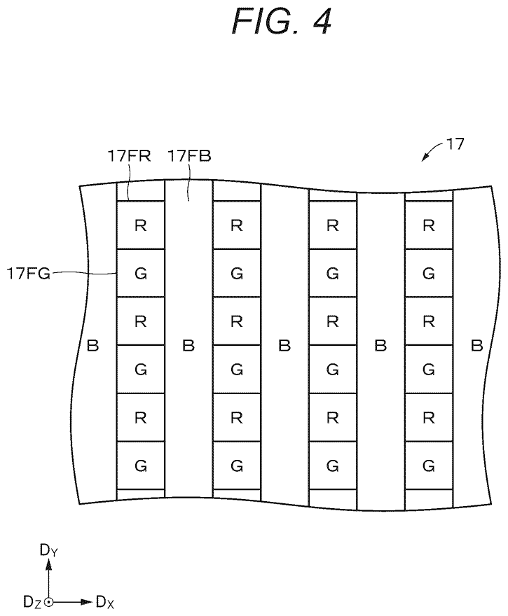

FIG. 4 is a plan view of the color filter 17. The color filter 17 is provided above the plurality of light emitting elements 12W. More specifically, the color filter 17 is provided on the first surface of the planarization layer 16 in the effective pixel region RE1. The color filter 17 is, for example, an on-chip color filter (OCCF). The color filter 17 includes, for example, a plurality of red filter portions 17FR, a plurality of green filter portions 17FG, and a plurality of blue filter portions 17FB. Note that, in the following description, the red filter portions 17FR, the green filter portions 17FG, and the blue filter portions 17FB will be collectively referred to as a filter portion 17F in a case where the red filter portions 17FR, the green filter portions 17FG, and the blue filter portions 17FB are not particularly distinguished from one another.

The plurality of filter portions 17F is two-dimensionally arranged on the first surface of the planarization layer 16 in a prescribed arrangement pattern. The prescribed arrangement pattern is as described as the prescribed arrangement pattern of the plurality of sub-pixels 10. Each filter portion 17F is provided above one of the light emitting elements 12W. The red filter portions 17FR and the light emitting elements 12W together constitute the sub-pixels 10R, the green filter portions 17FG and the light emitting elements 12W together constitute the sub-pixels 10G, and the blue filter portions 17FB and the light emitting elements 12W together constitute the sub-pixels 10B.

The red filter portions 17FR can transmit red light out of the white light emitted from the light emitting elements 12W and absorb light other than the red light. The green filter portions 17FG can transmit green light out of the white light emitted from the light emitting elements 12W and absorb light other than the green light. The blue filter portions 17FB can transmit blue light out of the white light emitted from the light emitting elements 12W and absorb light other than the blue light.

The red filter portions 17FR include, for example, red color resist. The green filter portions 17FG include, for example, green color resist. The blue filter portions 17FB include, for example, blue color resist.

### (Light Shielding Layer 17BK)

The light shielding layer 17BK is provided on the first surface of the planarization layer 16 in the peripheral region RE2. The light shielding layer 17BK is preferably provided above the contact portion 124 and covers the contact portion 124. The light shielding layer 17BK can absorb and shield external light (visible light) incident on the peripheral region RE2. Therefore, reflection of external light by the contact portion 124 or the like can be suppressed.

The light shielding layer 17BK may have a closed loop shape surrounding the entire outer periphery of the effective pixel region RE1 in plan view, or may have a partially divided loop shape partially surrounding the outer periphery of the effective pixel region RE1.

The light shielding layer 17BK preferably includes the red filter portion 17FR and the blue filter portion 17FB. Since the light shielding layer 17BK has such a configuration, the light shielding layer 17BK can be simultaneously formed in the process of forming the color filter 17. However, the configuration of the light shielding layer 17BK is not limited thereto, and may be, for example, a light shielding layer containing a black light absorption material. The black light absorption material contains, for example, at least one selected from a group including a black resin material and a black metal-containing material. The black resin material includes, for example, a carbon material such as carbon black. The black resin material may contain, for example, a black color resist and the like. The black metal-containing material includes, for example, titanium nitride (TiNx) or the like.

### (Near-Infrared Absorption Layer 18)

The near-infrared absorption layer 18 can absorb near infrared rays. Therefore, reflection of near infrared rays can be suppressed in the display device 101. In the present specification, near infrared rays represent light (electromagnetic wave) having a wavelength of 700 nm or more and 2500 nm or less. The near-infrared absorption layer 18 is provided in the effective pixel region RE1 and the peripheral region RE2 located around the effective pixel region RE1. Therefore, reflection of near infrared rays can be suppressed in both the effective pixel region RE1 and the peripheral region RE2. The near-infrared absorption layer 18 is provided inside the cover glass 20. Therefore, deterioration of the near-infrared absorption layer 18 can be suppressed.

The near-infrared absorption layer 18 preferably includes a photoresist and a near-infrared absorption material. Since the near-infrared absorption layer 18 includes a photoresist, a pattern portion 181 having a desired pattern can be easily formed by a photolithography technique.

The near-infrared absorption material contains, for example, at least one selected from a group including an organic compound and a metal complex. More specifically, the near-infrared absorption material contains, for example, at least one selected from a group including a diimmonium compound, an aminium compound, a phthalocyanine compound, an organometallic complex, a cyanine compound, an azo compound, a polymethine compound, a quinone compound, a diphenylmethane compound, a triphenylmethane compound, a metal oxide, and the like. The metal oxide includes, for example, at least one selected from a group including tungsten oxide, composite tungsten oxide, and the like. The near-infrared absorption material may be particles.

The near-infrared absorption layer 18 preferably includes a pattern portion 181 and a non-pattern portion 182.

### (Pattern Portion 181)

The pattern portion 181 is provided on the first surface of the color filter 17 in the effective pixel region RE1. Since the near-infrared absorption layer 18 has the pattern portion 181 in the effective pixel region RE1, absorption of the emitted light by the near-infrared absorption layer 18 can be suppressed. Accordingly, it is possible to suppress a decrease in luminance of the display device 101 due to the near-infrared absorption layer 18.

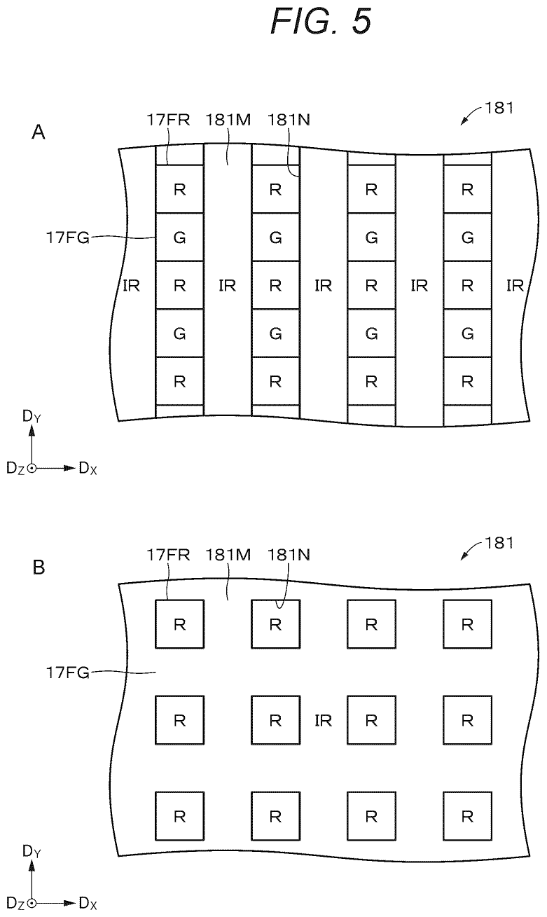

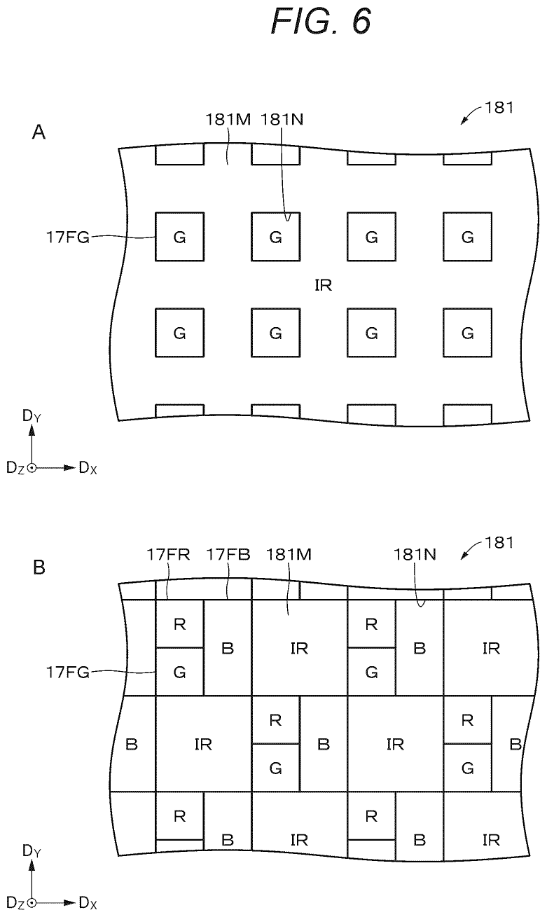

For example, the pattern portion 181 may have a pattern of a stripe shape (see FIG. 5A), a lattice shape (see FIGS. 5B and 6A), or a checkered pattern shape (FIG. 6B), or may have other patterns. The pattern portion 181 has one or a plurality of near-infrared absorption portions 181M and a plurality of opening portions 181N. The plurality of opening portions 181N is two-dimensionally arranged in a prescribed arrangement pattern on the first surface of the color filter 17. The opening portion 181N is preferably provided at the position of the filter portion 17F of at least one color among the filter portions 17FR, 17FG, and 17FB of a plurality of colors (three colors). The near-infrared absorption portion 181M is preferably provided at a position of the filter portion 17F other than the filter portion 17F of at least one color.

### (Arrangement in Units of Sub-Pixels)

As illustrated in FIGS. 5A, 5B, and 6A, the opening portion 181N may be provided with the sub-pixel 10 as a minimum unit, and the near-infrared absorption portion 181M may be provided with the sub-pixel 10 as a minimum unit. More specifically, the opening portion 181N may be provided at the position of the sub-pixel 10 of one prescribed color among the sub-pixels 10R, 10G, and 10B, and the near-infrared absorption portion 181M may be provided at the positions of the sub-pixels 10 of two colors other than the sub-pixel 10 of one prescribed color.

Alternatively, the opening portion 181N may be provided at the position of the sub-pixel 10 of two prescribed colors among the sub-pixels 10R, 10G, and 10B, and the near-infrared absorption portion 181M may be provided at the positions of the sub-pixels 10 of one color other than the sub-pixel 10 of two prescribed colors.

Examples of patterns in which the opening portion 181N is provided at the position of the sub-pixel 10 of one prescribed color among the sub-pixels 10R, 10G, and 10B, and the near-infrared absorption portion 181M is provided at the position of the sub-pixel 10 of two colors other than the sub-pixel 10 of one prescribed color include the following patterns (1), (2), and (3).

Pattern (1): The opening portion 181N is provided at the position of the sub-pixel 10R among the sub-pixels 10R, 10G, and 10B, and the near-infrared absorption portion 181M is provided at the positions of the sub-pixels 10G and 10B among the sub-pixels 10R, 10G, and 10B (see FIG. 5B).

Pattern (2): The opening portion 181N is provided at the position of the sub-pixel 10G among the sub-pixels 10R, 10G, and 10B, and the near-infrared absorption portion 181M is provided at the positions of the sub-pixels 10R and 10B among the sub-pixels 10R, 10G, and 10B (see FIG. 6A).

Pattern (3): The opening portion 181N is provided at the position of the sub-pixel 10B among the sub-pixels 10R, 10G, and 10B, and the near-infrared absorption portion 181M is provided at the positions of the sub-pixels 10R and 10G among the sub-pixels 10R, 10G, and 10B.

From the viewpoint of suppressing a decrease in luminance due to the near-infrared absorption portion 181M, the pattern (1) is preferable among the pattern (1), the pattern (2), and the pattern (3).

Examples of patterns in which the opening portion 181N is provided at the positions of the sub-pixels 10 of two prescribed colors among the sub-pixels 10R, 10G, and 10B, and the near-infrared absorption portion 181M is provided at the position of the sub-pixel 10 of one color other than the sub-pixels 10 of two prescribed colors include the following patterns (4), (5), and (6).

Pattern (4): The opening portion 181N is provided at the positions of the sub-pixels 10G and 10B among the sub-pixels 10R, 10G, and 10B, and the near-infrared absorption portion 181M is provided at the position of the sub-pixel 10R among the sub-pixels 10R, 10G, and 10B.

Pattern (5): The opening portion 181N is provided at the positions of the sub-pixels 10R and 10B among the sub-pixels 10R, 10G, and 10B, and the near-infrared absorption portion 181M is provided at the position of the sub-pixel 10G among the sub-pixels 10R, 10G, and 10B.

Pattern (6): The opening portion 181N is provided at the positions of the sub-pixels 10R and 10G among the sub-pixels 10R, 10G, and 10B, and the near-infrared absorption portion 181M is provided at the position of the sub-pixel 10B among the sub-pixels 10R, 10G, and 10B (see FIG. 5A).

From the viewpoint of suppressing a decrease in luminance due to the near-infrared absorption portion 181M, the pattern (5) and the pattern (6) are preferable among the pattern (4), the pattern (5), and the pattern (6).

### (Arrangement in Units of Pixels)

As illustrated in FIG. 6B, the opening portion 181N may be provided with a pixel 10Px as a minimum unit, and the near-infrared absorption portion 181M may be provided with a pixel 10Px as a minimum unit. The plurality of near-infrared absorption portions 181M and the plurality of opening portions 181N may be two-dimensionally arranged. For example, the near-infrared absorption portions 181M and the opening portions 181N may be alternately arranged in the first direction (for example, the horizontal direction DX) and alternately arranged in the second direction (for example, the vertical direction DY).

### (Non-pattern Portion 182)

The non-pattern portion 182 is a layer having no pattern as in the pattern portion 181. The non-pattern portion 182 is provided on the first surface of the protective layer 19 in the peripheral region RE2. That is, the non-pattern portion 182 is provided above the light shielding layer 17BK in the peripheral region RE2. Since the near-infrared absorption layer 18 has the non-pattern portion 182 in the peripheral region RE2, near infrared rays incident on the peripheral region RE2 can be absorbed. Accordingly, the effect of suppressing reflection of near infrared rays in the display device 101 can be further improved.

The non-pattern portion 182 may have a closed loop shape surrounding the entire outer periphery of the effective pixel region RE1 in plan view, or may have a partially divided loop shape partially surrounding the outer periphery of the effective pixel region RE1.

### (Protective Layer 19)

The protective layer 19 covers and protects the color filter 17, the pattern portion 181, the light shielding layer 17BK, and the like. The protective layer 19 may also serve as an adhesive layer for bonding the cover glass 20 and the drive board 11 on which each member such as the plurality of light emitting elements 12W is provided on the first surface.

The protective layer 19 has translucency with respect to light emitted from the light emitting element 12W. The protective layer 19 preferably has transparency to visible light. The protective layer 19 contains, for example, at least one selected from a group including a thermosetting resin, an ultraviolet curable resin, thermosetting resin and the like. Note that the protective layer 19 may contain a kind of curable resin other than the thermosetting resin and the ultraviolet curable resin.

### (Cover Glass 20)

The cover glass 20 is provided on the first surface of the protective layer 19 and the first surface of the non-pattern portion 182. The cover glass 20 seals each member such as the plurality of light emitting elements 12W provided on the first surface on the drive board 11. The cover glass 20 has translucency with respect to light emitted from the light emitting element 12W. The cover glass 20 preferably has transparency to visible light. The cover glass 20 is, for example, a glass substrate.

(Translucent characteristics of Color Filter 17 and Near-Infrared Absorption Layer 18)

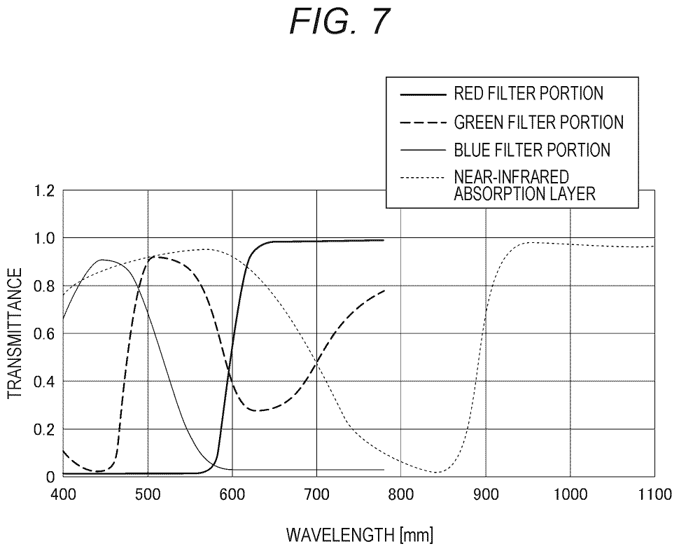

FIG. 7 illustrates an example of transmission spectra of the red filter portion 17FR, the green filter portion 17FG, the blue filter portion 17FB, and the near-infrared absorption layer 18. Ideally, the near-infrared absorption layer 18 desirably has a characteristic of absorbing only the electromagnetic wave in the near-infrared region or a characteristic of absorbing only the electromagnetic wave in the near-infrared region and a wavelength range longer than this region. However, as illustrated in FIG. 7, in general, the near-infrared absorption layer has absorbability in a wavelength range of visible light shorter than the near-infrared region, particularly in a wavelength range of red light. Therefore, the luminance performance of the display device 101 may change depending on the position of the opening portion 181N of the pattern portion 181 of the near-infrared absorption layer 18. Accordingly, it is preferable that the near-infrared absorption layer 18 has the pattern portion 181 in the effective pixel region RE1, and the pattern portion 181 has the opening portion 181N at least at the position of the sub-pixel 10R, that is, at least at the position of the red filter portion 17FR. As a specific pattern of the pattern portion 181, as described above, the pattern (1), the pattern (5), or the pattern (6) is preferable.

### [Method for Manufacturing Display Device 101]

Hereinafter, an example of a method for manufacturing the display device 101 according to one embodiment will be described.

### (Process of Forming First Electrode 121 and Contact Portion 124)

First, a metal layer and a metal oxide layer are sequentially formed on the first surface of a drive board 11 by, for example, a sputtering method, and then the metal layer and the metal oxide layer are patterned using, for example, a photolithography technique and an etching technique. Therefore, the plurality of first electrodes 121 and the contact portion 124 are formed on the first surface of the drive board 11.

### (Process of Forming Insulating Layer 13)

Next, the insulating layer 13 is formed on the first surface of the drive board 11 to cover the plurality of first electrodes 121 and the contact portion 124 by, for example, a chemical vapor deposition (CVD) method. Next, an opening is formed in a portion of the insulating layer 13 located on the first surface of each of the first electrodes 121 and a portion located on the first surface of the contact portion 124 by, for example, a photolithography technique and a dry etching technique.

### (Process of Forming OLED Layer 122)

Next, a hole transport layer, a red light emitting layer, a light emitting separation layer, a blue light emitting layer, a green light emitting layer, an electron transport layer, and an electron injection layer are stacked in this order on the first surfaces of the plurality of first electrodes 121 and the first surface of the drive board 11 by, for example, a vapor deposition method, thereby forming the OLED layer 122.

### (Process of Forming Second Electrode 123)

Next, the second electrode 123 is formed on the first surface of the OLED layer 122 and the first surface of the contact portion 124 by, for example, a vapor deposition method or a sputtering method. Therefore, the plurality of light emitting elements 12W is formed on the first surface of the drive board 11, and the peripheral edge portion of the second surface of the second electrode 123 is connected to the contact portion 124.

### (Process of Forming Protective Layer 14)

Next, the protective layer 14 is formed on the first surface of the second electrode 123 by, for example, the CVD method or the vapor deposition method.

### (Process of Forming Protective Layer 15)

Next, the protective layer 15 is formed on the first surface of the protective layer 14 by, for example, atomic layer deposition (ALD).

### (Process of Forming Planarization Layer 16)

Next, the planarization layer 16 is formed on the first surface of the protective layer 15 by, for example, the CVD method or the vapor deposition method.

### (Process of Forming Color Filter 17 and Light Shielding Layer 17BK)

Next, a coloring composition for forming a green filter portion is applied onto the first surface of the planarization layer 16, and after pattern exposure by irradiation with ultraviolet rays through a photomask, development is performed to form the green filter portion 17FG. Next, a coloring composition for forming a red filter portion is applied onto the first surface of the planarization layer 16, and after pattern exposure by irradiation with ultraviolet rays through a photomask, development is performed to form the red filter portion 17FR. Next, a coloring composition for forming a blue filter portion is applied onto the first surface of the planarization layer 16, and after pattern exposure by irradiation with ultraviolet rays through a photomask, development is performed to form the blue filter portion 17FB. Therefore, the color filter 17 and the light shielding layer 17BK are formed on the first surface of the planarization layer 16.

### (Process of Forming Pattern Portion 181)

Next, a composition for forming a near-infrared absorption layer is applied onto the first surface of the color filter 17, and after pattern exposure by irradiation with ultraviolet rays through a photomask, development is performed to form the pattern portion 181. As the composition for forming a near-infrared absorption layer, for example, a photoresist to which a near-infrared absorption material is added is used.

### (Process of Sealing)

Next, the composition for forming the near-infrared absorption layer is applied onto the peripheral edge portion of the second surface of the cover glass 20, and irradiated with ultraviolet rays to form the non-pattern portion 182. Next, a curable resin is applied onto the first surface of the planarization layer 16 so as to cover the pattern portion 181 and the light shielding layer 17BK. The curable resin contains, for example, at least one selected from a group including a thermosetting resin, an ultraviolet curable resin, and the like.

Next, the cover glass 20 is placed on the curable resin such that the second surface of the cover glass 20 faces the curable resin. Next, for example, the curable resin is cured by at least one of heat treatment and ultraviolet irradiation treatment to form the protective layer 19. Therefore, the drive board 11 on which the respective members such as the plurality of light emitting elements 12W are provided on the first surface and the cover glass 20 are bonded together by the protective layer 19. Note that the curing method of the curable resin is not limited to the heat treatment and the ultraviolet irradiation treatment, and may be a curing method other than the heat treatment and the ultraviolet irradiation treatment. With the above-described procedures, the display device 101 illustrated in FIG. 3 is obtained.

### Operations and Effects

In the display device 101 according to one embodiment, the near-infrared absorption layer 18 is provided in the effective pixel region RE1 and the peripheral region RE2 located around the effective pixel region RE1. Therefore, reflection of near infrared rays can be suppressed in both the effective pixel region RE1 and the peripheral region RE2. Accordingly, in a case where the display device 101 is provided in the eyewear device, the generation of stray light of near infrared rays can be suppressed.

The near-infrared absorption layer 18 has a pattern portion 181 in the effective pixel region RE1. Therefore, it is possible to suppress a decrease in luminance of the display device 101 due to the provision of the near-infrared absorption layer 18.

Furthermore, a desired transmittance can be obtained by adjusting the pattern of the pattern portion 181. Accordingly, it is possible to suppress a decrease in the degree of freedom in designing the display device 101 due to the provision of the near-infrared absorption layer 18.

As a display device capable of suppressing reflection of near infrared rays, an on-cell type display device in which a near-infrared absorbing film is bonded to a display surface is conceivable. However, the process of bonding the near-infrared absorbing film to the first surface (display surface) may cause an increase in cost of the display device. On the other hand, the display device 101 according to one embodiment is an in-cell display device including the near-infrared absorption layer 18 therein. Therefore, the process of bonding the near-infrared absorbing film to the display surface may not be provided.

Accordingly, it is possible to suppress an increase in cost of the display device 101 due to the addition of the function of suppressing near-infrared reflection.

### 2 EXAMPLES

Hereinafter, the present disclosure will be specifically described with reference to examples, but the present disclosure is not limited to these examples.

### Example 1

The display device of Example 1 is a display device corresponding to the display device 101 according to one embodiment. The color filter has a configuration illustrated in FIG. 4. The pattern portion of the near-infrared absorption layer has the configuration illustrated in FIG. 5A.

### Example 2

The display device of Example 1 is a display device corresponding to the display device 101 according to one embodiment. The color filter has a configuration illustrated in FIG. 4. The pattern portion of the near-infrared absorption layer has the configuration illustrated in FIG. 5B.

### Example 3

The display device of Example 1 is a display device corresponding to the display device 101 according to one embodiment. The color filter has a configuration illustrated in FIG. 4. The pattern portion of the near-infrared absorption layer has the configuration illustrated in FIG. 6B.

### Comparative Example 1

The display device of Comparative Example 1 does not include a near-infrared absorption layer on the color filter.

The color filter has a configuration illustrated in FIG. 4.

### Comparative Example 2

The display device of Comparative Example 2 includes a near-infrared absorption layer on the color filter. The color filter has a configuration illustrated in FIG. 4. The near-infrared absorption layer covers the entire color filter, that is, the filter portions of all colors of the red filter portion, the green filter portion, and the blue filter portion.

Table 1 shows luminance characteristics and IR cut functions of the display devices of Examples 1 to 3 and Comparative Examples 1 and 2.

TABLE 1

| | Presence or | | | | |
|---|---|---|---|---|---|
| | absence of | | | | |
| | near-infrared | Shape of | Formation | | |
| | absorption | pattern | position of | | |
| | layer | portion | opening portion | Luminance | IR cut |
| Example 1 | Presence | Stripe shape | Red filter portion | 3 | 2 |
| | | (see FIG. 5A) | and green filter | | |
| | | | portion | | |
| Example 2 | Presence | Lattice shape | Red filter portion | 2 | 3 |
| | | (see FIG. 5B) | | | |
| Example 3 | Presence | Checkered | Opening portions | 2 | 3 |
| | | pattern shape | are arranged in | | |
| | | (see FIG. 6B) | horizontal and | | |
| | | | vertical directions | | |
| | | | at every other pixel | | |
| | | | in units of pixels | | |
| Comp. | Absence | — | — | 4 | 1 |
| example 1 | | | | | |
| Comp. | Presence | — | No opening portion | 1 | 4 |
| example 2 | | | | | |

In Table 1, the meanings of the numerical values of 1 to 4 in the luminance characteristics are as follows.

The reference numerals 1 to 4 denote the order of the luminance heights, and the luminance increases in the order of 1, 2, 3, and 4.

In Table 1, the meanings of the numerical values of 1 to 4 in the IR cut-off function are as follows.

The numeral values 1 to 4 denote the order of the height of the IR cutting function (the height of the near-infrared ray absorption ability), and the IR cutting function is assumed to be higher in the order of 1, 2, 3, and 4.

From Table 1, it can be seen that the near-infrared absorption layer on the color filter preferably has a pattern from the viewpoint of achieving both luminance characteristics and an IR cut function.

### 3 MODIFICATIONS

### Modification 1

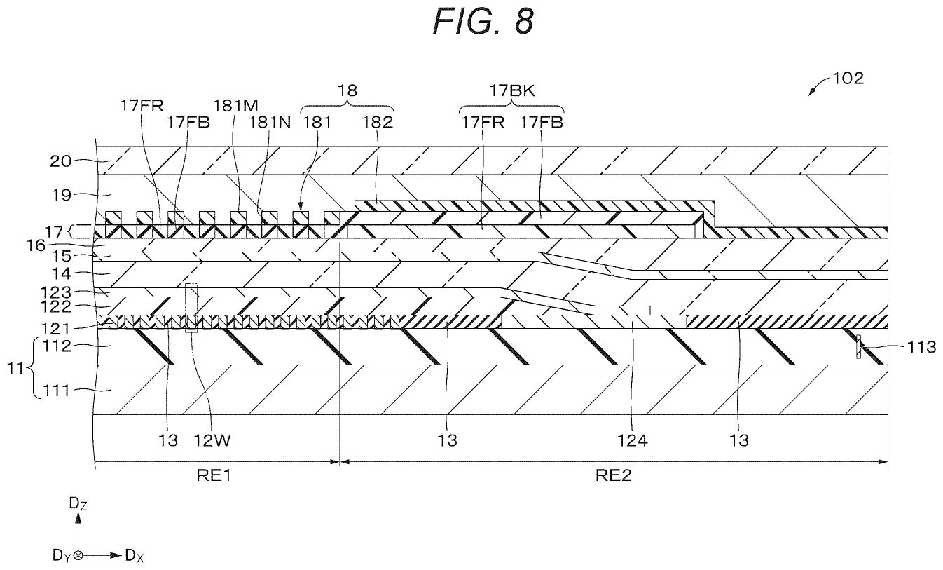

FIG. 8 is a cross-sectional view of a display device 102 according to Modification 1. The display device 102 is different from the display device 101 (see FIG. 3) according to one embodiment in that the non-pattern portion 182 of the near-infrared absorption layer 18 is provided on the first surface of the light shielding layer 17BK instead of the non-pattern portion 182 of the near-infrared absorption layer 18 on the first surface of the protective layer 19.

Note that the display device 102 may include the non-pattern portion 182 of the near-infrared absorption layer 18 on the first surface of the protective layer 19, and may also include the non-pattern portion 182 of the near-infrared absorption layer 18 on the first surface of the light shielding layer 17BK. In a case where the peripheral edge portion of the first surface of the planarization layer 16 is not covered with the light shielding layer 17BK, the near-infrared absorption layer 18 may cover the peripheral edge portion of the first surface of the planarization layer 16. In the present specification, the peripheral edge portion of the first surface refers to a region having a predetermined width from the peripheral edge of the first surface toward the inside.

### Modification 2

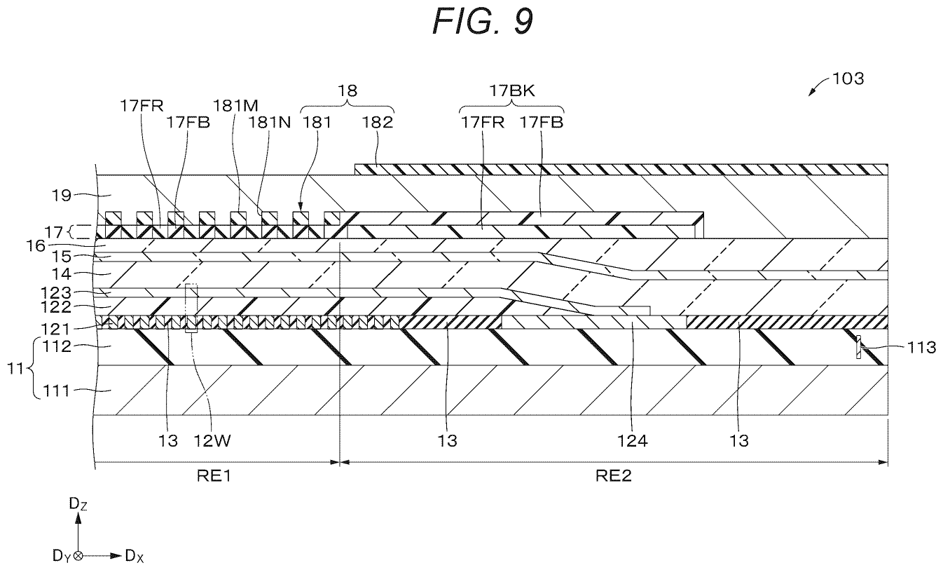

FIG. 9 is a cross-sectional view of a display device 103 according to Modification 2. The display device 103 is different from the display device 101 (see FIG. 3) according to one embodiment in that the cover glass 20 is not provided and the protective layer 19 and the non-pattern portion 182 of the near-infrared absorption layer 18 are exposed.

### Modification 3

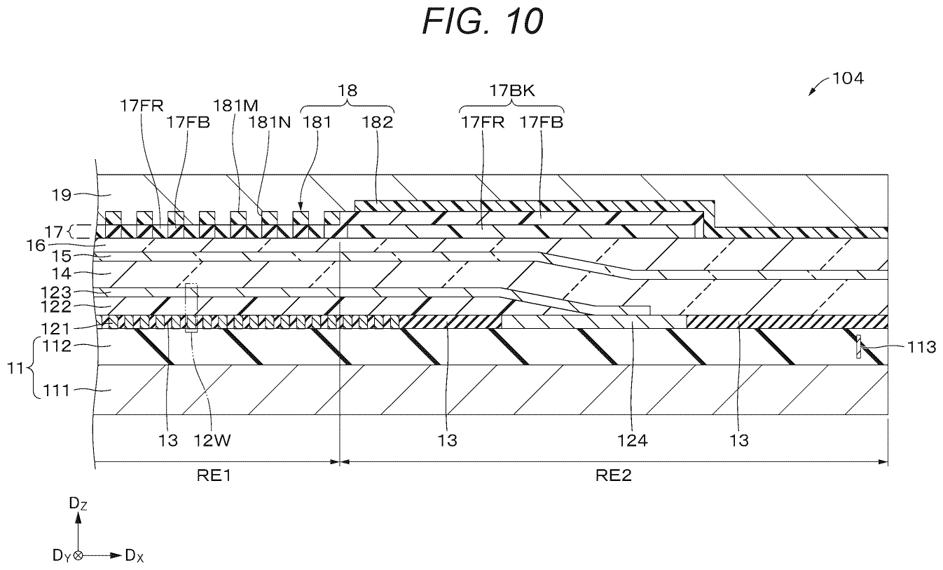

FIG. 10 is a cross-sectional view of a display device 104 according to Modification 3. The display device 104 is different from the display device 102 (see FIG. 8) according to Modification 1 in that the cover glass 20 is not provided and the protective layer 19 is exposed.

Note that the display device 104 may include the non-pattern portion 182 of the near-infrared absorption layer 18 on the first surface of the protective layer 19, and may also include the non-pattern portion 182 of the near-infrared absorption layer 18 on the first surface of the light shielding layer 17BK. In a case where the peripheral edge portion of the first surface of the planarization layer 16 is not covered with the light shielding layer 17BK, the near-infrared absorption layer 18 may cover the peripheral edge portion of the first surface of the planarization layer 16.

### Modification 4

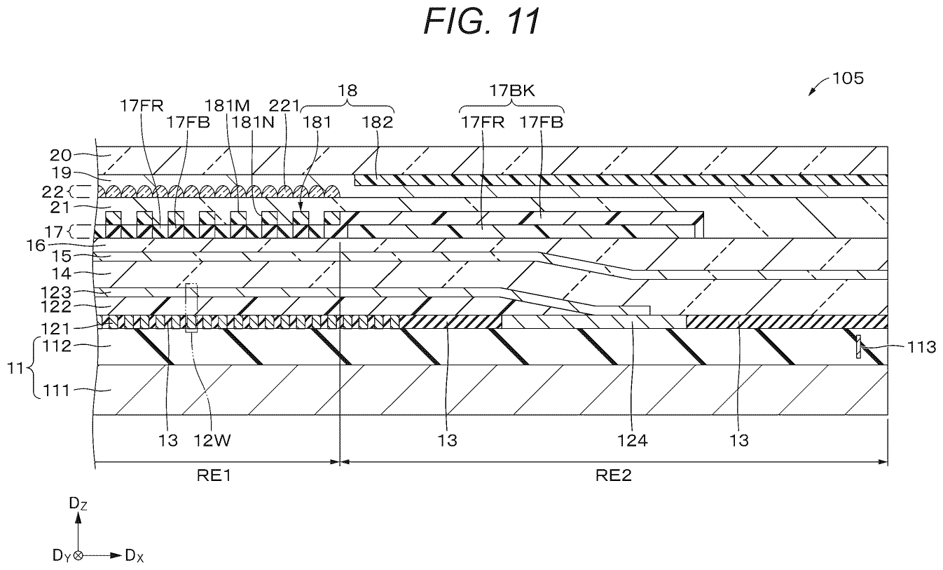

FIG. 11 is a cross-sectional view of a display device 105 according to Modification 4. The display device 104 is different from the display device 101 (see FIG. 3) according to one embodiment in further including a planarization layer 21 and a lens array 22.

### (Planarization Layer 21)

The planarization layer 21 covers the pattern portion 181 of the near-infrared absorption layer 18 and the light shielding layer 17BK, and forms a flat surface above the first surface of the pattern portion 181 and above the first surface of the light shielding layer 17BK. The planarization layer 21 includes, for example, an inorganic material or a polymer resin. As the inorganic material, a material similar to the inorganic material of the protective layer 14 can be exemplified. As the polymer resin, a material similar to the polymer resin of the protective layer 14 can be exemplified.

### (Lens Array 22)

The lens array 22 is provided on the first surface of the planarization layer 21. The lens array 22 contains a plurality of lenses 221. The lens 221 can condense the light emitted upward from the light emitting element 12W in the front direction. The plurality of lenses 221 is so-called on-chip microlenses (OCL), and are two-dimensionally arranged on the first surface of the planarization layer 21 in a prescribed arrangement pattern.

One lens 221 may be provided above one light emitting element 12W, or two or more lenses 221 may be provided above one light emitting element 12W. FIG. 11 illustrates an example in which one lens 221 is provided above one light emitting element 12W. The lens 221 may have a curved surface on the surface side from which the light incident from the light emitting element 12W is emitted. The curved surface may be a convex curved surface protruding in a direction away from the light emitting element 12W or a concave curved surface recessed in a direction approaching the light emitting element 12W. Examples of the curved surface include, but are not limited to, a substantially parabolic shape, a substantially hemispherical shape, and a substantially semielliptical shape.

The lens 221 contains, for example, an inorganic material or a polymer resin each being transparent to visible light. The inorganic material includes, for example, silicon oxide (SiOx). The polymer resin contains, for example, an ultraviolet curable resin.

### (Protective Layer 19)

The protective layer 19 covers the lens array 22 and the planarization layer 21. The refractive index of the protective layer 19 is different from the refractive index of the lens array 22. The refractive index of the protective layer 19 may be higher or lower than the refractive index of the lens array 22. In a case where the lens 221 has a convex curved surface on the emission surface side, the refractive index of the protective layer 19 is preferably lower than the refractive index of the lens array 22 from the viewpoint of improving the front luminance. In a case where the lens 221 has a concave curved surface on the emission surface side, the refractive index of the protective layer 19 is preferably higher than the refractive index of the lens array 22 from the viewpoint of improving the front luminance.

### Modification 5

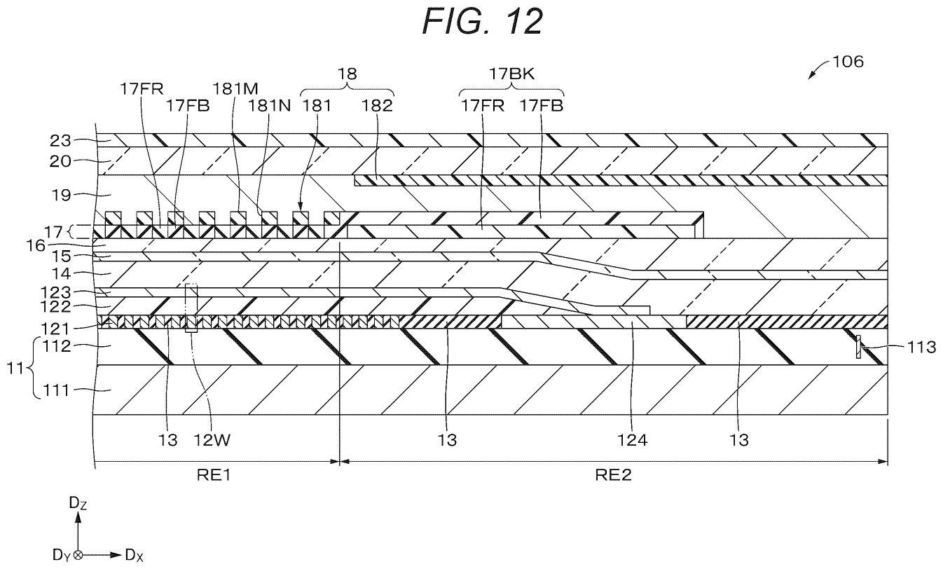

FIG. 12 is a cross-sectional view of a display device 106 according to Modification 5. The display device 106 is different from the display device 101 according to one embodiment (see FIG. 3) in that it further includes a reflection suppressing layer 23. The reflection suppressing layer 23 can suppress visible light reflection. The reflection suppressing layer 23 is, for example, an anti-reflective (AR) layer, a low reflective (LR) layer, or a moth-eye structure layer.

### Modification 6

In the above one embodiment, an example in which the display device 101 includes the plurality of light emitting elements 12W capable of emitting white light has been described, but the plurality of light emitting elements included in the display device 101 is not limited to the plurality of light emitting elements 12W.

For example, instead of the plurality of light emitting elements 12W or together with the plurality of light emitting elements 12W, the display device 101 may include a plurality of first light emitting elements capable of emitting red light, a plurality of second light emitting elements capable of emitting green light, and a plurality of third light emitting elements capable of emitting blue light. In the case of this configuration, the display device 101 may include the color filter 17 or may not include the color filter 17.

### Modification 7

In the above one embodiment, the example in which the pattern portion 181 of the near-infrared absorption layer 18 is provided on the first surface of the color filter 17 in the effective pixel region RE1 has been described, but the color filter 17 and the pattern portion 181 of the near-infrared absorption layer 18 may not be adjacent to each other. For example, the pattern portion 181 of the near-infrared absorption layer 18 may be provided above the color filter 17.

### Modification 8

In the above one embodiment, the example in which the near-infrared absorption layer 18 includes the non-pattern portion 182 in the peripheral region RE2 has been described, but the near-infrared absorption layer 18 may include the pattern portion in the peripheral region RE2. The pattern portion may have a pattern similar to the pattern portion 181 of the effective pixel region RE1, or may have a pattern different from the pattern portion 181 of the effective pixel region RE1.

### Other Modifications

Although one embodiment of the present disclosure, examples, and modifications have been specifically described above, the present disclosure is not limited to the above one embodiment, examples, and modifications, and various modifications based on the technical idea of the present disclosure can be made.

For example, the configurations, methods, processes, shapes, materials, numerical values, and the like listed in the above one embodiment, examples, and modifications are merely examples, and configurations, methods, processes, shapes, materials, numerical values, and the like different therefrom may be used as necessary.

The configurations, methods, steps, shapes, materials, numerical values, and the like of the above one embodiment, examples, and modifications can be combined with each other without departing from the gist of the present disclosure.

The materials exemplified in the above one embodiment, examples, and modifications may be used alone or in combination of two or more unless otherwise specified.

In the above one embodiment, examples, and modifications, an example in which the light emitting element is an OLED element has been described, but the light emitting element is not limited to this example, and may be a light emitting element of a self light emitting type such as a light emitting diode (LED), an inorganic electro-luminescence (IEL) element, or a semiconductor laser element. Two or more types of light emitting elements may be provided in the display device.

In the above one embodiment, examples, and modifications, an example in which the light emitting device is the display device has been described. However, the light emitting device is not limited to the display device, and may be a lighting device or the like.

Furthermore, the present disclosure can also adopt the following configurations.

(1)

A light emitting device including:
a near-infrared absorption layer, in which
the near-infrared absorption layer is provided in an effective pixel region and a peripheral region located around the effective pixel region, and
the near-infrared absorption layer includes a pattern portion in the effective pixel region.

(2)

The light emitting device according to (1), in which
the near-infrared absorption layer includes a non-pattern portion in the peripheral region.

(3)

The light emitting device according to (1) or (2), in which
the pattern portion has a plurality of opening portions,
the plurality of opening portions is two-dimensionally arranged, and
each of the opening portions is provided in units of sub-pixels or pixels.

(4)

The light emitting device according to (1) or (2), further including:
a color filter, in which
the color filter includes a filter portion of a plurality of colors,
the pattern portion has a plurality of openings, and
each of the opening portions is provided at a position of at least one of the filter portions of the plurality of colors.

(5)

The light emitting device according to (1) or (2), further including:
a color filter, in which
the color filter includes a red filter portion, a green filter portion, and a blue filter portion,
the pattern portion has a plurality of opening portions, and
each of the opening portions is provided at a position of the red filter portion.

(6)

The light emitting device according to (1) or (2), further including:
a color filter, in which
the color filter includes a red filter portion, a green filter portion, and a blue filter portion,
the pattern portion has a plurality of opening portions, and
the opening portions each are provided at positions of the red filter portion and the green filter portion.

(7)

The light emitting device according to any one of (1) to (3), further including:
a color filter, in which
the pattern portion is provided on the color filter or above the color filter.

(8)

The light emitting device according to (2), further including:
a light shielding layer, in which
the light shielding layer is provided in the peripheral region, and
the non-pattern portion is provided on the light shielding layer or above the light shielding layer.

(9)

The light emitting device according to (2), further including:
a light shielding layer; and
a protective layer, in which
the light shielding layer is provided in the peripheral region,
the protective layer covers the pattern portion and the light shielding layer, and
the non-pattern portion is provided on the protective layer.

(10)

The light emitting device according to any one of (1) to (9), in which
the near-infrared absorption layer includes a photoresist and a near-infrared absorption material.

(11)

The light emitting device according to any one of (1) to (10), further including:
a cover glass, in which
the near-infrared absorption layer is provided inside the cover glass.

(12)

The light emitting device according to any one of (1) to (11), further including:
a reflection suppressing layer capable of suppressing visible light reflection.

(13)

An eyewear device including:
the light emitting device according to any one of (1) to (12).

### 4 RELATIONSHIP AMONG NORMAL LINES EXTENDING THROUGH CENTERS OF LIGHT EMITTING UNITS, LENS MEMBERS, AND WAVELENGTH SELECTION UNITS

In the description below, the relationship among a normal line LN extending through the center of a light emitting unit, a normal line LN′ extending through the center of a lens member, and a normal line LN″ extending through the center of a wavelength selection unit is described. Here, the light emitting unit is, for example, the light emitting element 12W. The lens member is, for example, the lens 221 of the lens array 22. The wavelength selection unit is, for example, a filter portion 17F.

Note that the size of the wavelength selection units may be changed as appropriate in accordance with light emitted from the light emitting units, or, in a case where the light absorbing units (black matrix portions, for example) are provided between the wavelength selection units of adjacent light emitting units, the size of the light absorbing units may be changed as appropriate in accordance with light emitted from the light emitting units. Furthermore, the size of each wavelength selection unit may be changed as appropriate in accordance with the distance (offset amount) d0 between the normal line extending through the center of the light emitting unit and the normal line extending through the center of the wavelength selection unit. The planar shape of each wavelength selection unit may be the same as, similar to, or different from the planar shape of each lens member.

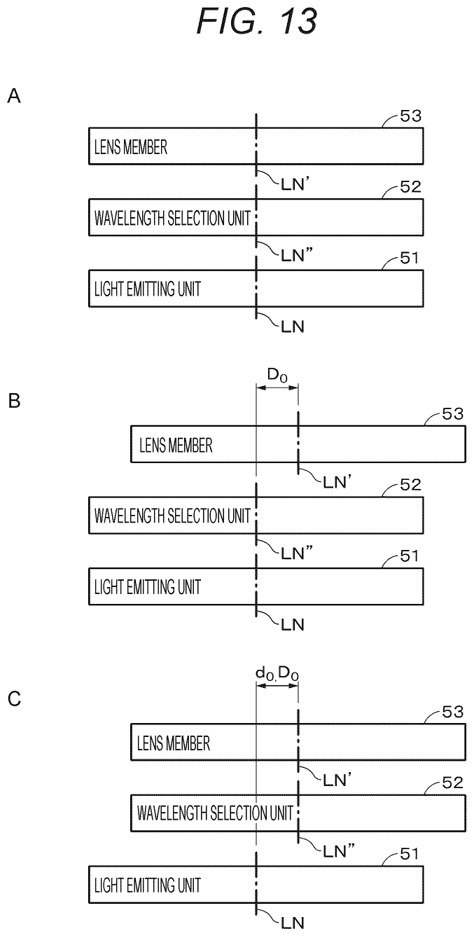

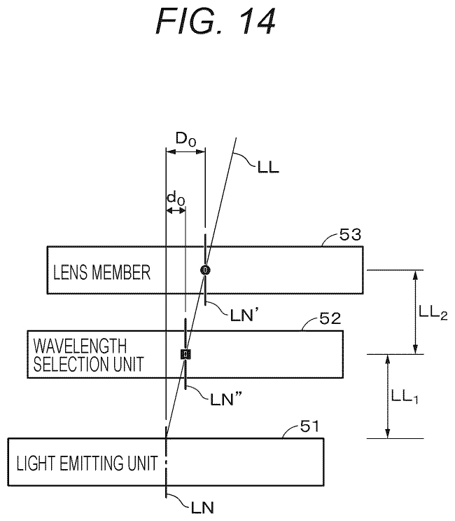

Hereinafter, with reference to FIGS. 13A, 13B, 13C, and 14, a relationship of a normal line passing through the center of each part in a case where a light emitting unit 51, a wavelength selection unit 52, and a lens member 53 are disposed in this order will be described.

As illustrated in FIG. 13A, the normal line LN extending through the center of the light emitting unit 51, the normal line LN″ extending through the center of the wavelength selection unit 52, and the normal line LN′ extending through the center of the lens member 53 may coincide with one another. That is, D0>0 and d0=0 may be satisfied. Here, DO represents the distance (offset amount) between the normal line LN extending through the center of the light emitting unit 51 and the normal line LN′ extending through the center of the lens member 53, and d0 represents the distance (offset amount) between the normal line LN extending through the center of the light emitting unit 51 and the normal line LN″ extending through the center of the wavelength selection unit 52.

As illustrated in a configuration in FIG. 13B, the normal line LN extending through the center of the light emitting unit 51 and the normal line LN″ extending through the center of the wavelength selection unit 52 may coincide with each other, but the normal line LN extending through the center of the light emitting unit 51 and the normal line LN″ extending through the center of the wavelength selection unit 52 may not coincide with the normal line LN′ extending through the center of the lens member 53. That is, D0>0 and d0=0 may be satisfied.

As illustrated in a configuration in FIG. 13C, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D0>0, d0>0, and D0=d0 may be satisfied.

As illustrated in a configuration in FIG. 14, the normal line LN extending through the center of the light emitting unit 51, the normal line LN″ extending through the center of the wavelength selection unit 52, and the normal line LN′ extending through the center of the lens member 53 may not coincide with one another. That is, D0>0, d0>0, and D0≠d0 may be satisfied. Here, the center of the wavelength selection unit 52 (the position indicated by a black square in FIG. 14) is preferably located on the straight line LL connecting the center of the light emitting unit 51 and the center of the lens member 53 (the position indicated by a black circle in FIG. 14). Specifically, when a distance in the thickness direction (in FIG. 14, the vertical direction) between the center of the light emitting unit 51 and the center of the wavelength selection unit 52 is LL1, and a distance in the thickness direction between the center of the wavelength selection unit 52 and the center of the lens member 53 is LL2,

D0>d0>0, and

considering manufacturing variations,

$$d 0 : D 0 = LL 1 : ( LL 1 + LL 2 )$$

is preferably satisfied.

Here, the thickness direction indicates the thickness direction of the light emitting unit 51, the wavelength selection unit 52, and the lens member 53.

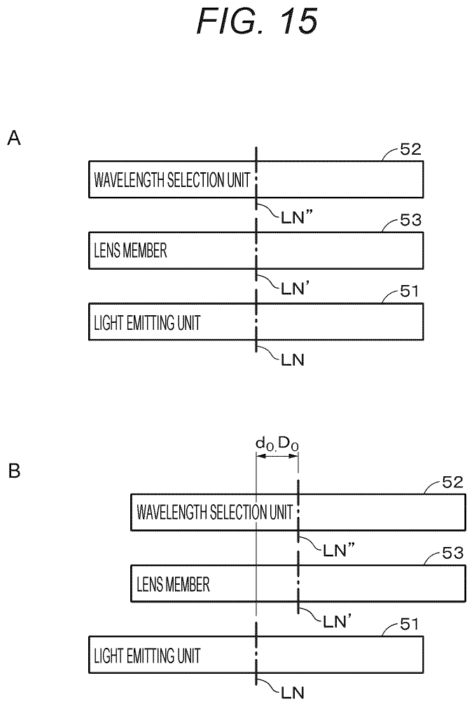

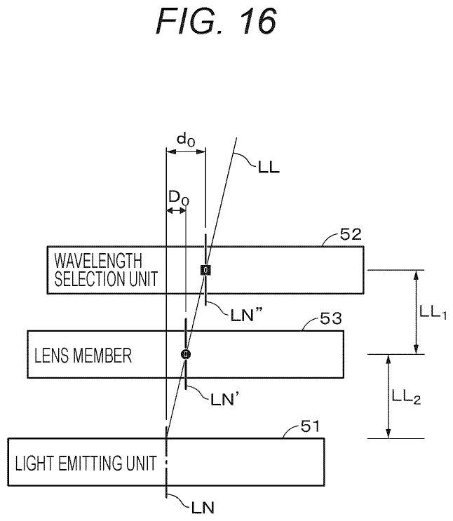

In the description below, referring to FIGS. 15A, 15B, and 16, the relationship among the normal lines extending through the center of the respective members in a case where the light emitting unit 51, the lens member 53, and the wavelength selection unit 52 are arranged in this order will be described.

As illustrated in a configuration in FIG. 15A, the normal line LN extending through the center of the light emitting unit 51, the normal line LN″ extending through the center of the wavelength selection unit 52, and the normal line LN′ extending through the center of the lens member 53 may coincide with one another. That is, D0>0 and d0=0 may be satisfied.

As illustrated in a configuration in FIG. 15B, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D0>0, d0>0, and D0=d0 may be satisfied.

As illustrated in a configuration in FIG. 16, the normal line LN extending through the center of the light emitting unit 51, the normal line LN″ extending through the center of the wavelength selection unit 52, and the normal line LN′ extending through the center of the lens member 53 may not coincide with one another. Here, the center of the lens member 53 (the position indicated by a black circle in FIG. 16) is preferably located on the straight line LL connecting the center of the light emitting unit 51 and the center of the wavelength selection unit 52 (the position indicated by a black square in FIG. 16). Specifically, when a distance in the thickness direction (in FIG. 16, the vertical direction) between the center of the light emitting unit 51 and the center of the lens member 53 is LL2, and a distance in the thickness direction between the center of the lens member 53 and the center of the wavelength selection unit 52 is LL1,

d0>D0>0, and

considering manufacturing variations,

$$D 0 : d 0 = LL 2 : ( LL 1 + LL 2 )$$

is preferably satisfied.
Here, the thickness direction indicates the thickness direction of the light emitting unit 51, the wavelength selection unit 52, and the lens member 53.

### 5 EXAMPLE OF RESONATOR STRUCTURE

The pixel used in the display device according to the present disclosure described above may have a resonator structure that causes resonance of light generated in the light emitting element. Hereinafter, the resonator structure will be described with reference to the drawings. Furthermore, in the following description, the first surface of each layer may be referred to as an upper surface.

### (Resonator Structure: First Example)

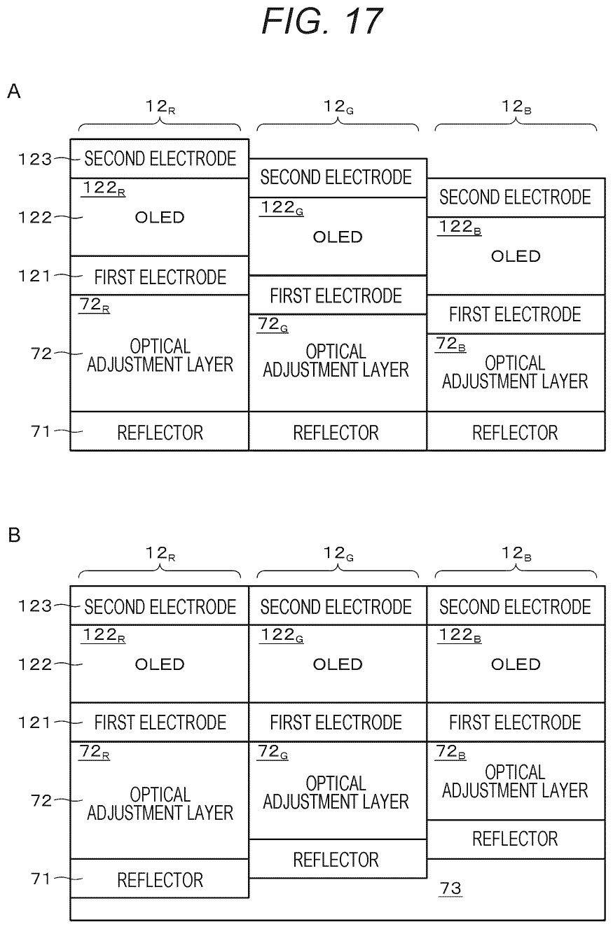

FIG. 17A is a schematic cross-sectional view for explaining a first example of the resonator structure. In the following description, in a case where the light emitting elements provided corresponding to the sub-pixels 10R, 10G, and 10B are collectively referred to without being particularly distinguished, they may be referred to as a light emitting element 12. In a case where the light emitting elements provided corresponding to the sub-pixels 10R, 10G, and 10B are distinguished, they may be referred to as light emitting elements 12R, 12G, and 12B. Portions of the OLED layer 122 corresponding to the sub-pixels 10R, 10G, and 10B may be referred to as an OLED layer 122R, an OLED layer 122G, and an OLED layer 122B, respectively.

In the first example, the first electrode 121 is formed to have a common film thickness in each light emitting element 12. This similarly applies to the second electrode 123.

A reflector 71 is disposed below the first electrode 121 of the light emitting element 12 with an optical adjustment layer 72 interposed therebetween. The resonator structure that causes resonance of light generated by the OLED layer 122 is formed between the reflector 71 and the second electrode 123. In the following description, the optical adjustment layers 72 provided corresponding to the sub-pixels 10R, 10G, and 10B may be referred to as optical adjustment layers 72R, 72G, and 72B, respectively.

The reflector 71 is formed to have a common film thickness in each light emitting element 12. The film thickness of the optical adjustment layer 72 is different according to a color to be displayed by the pixel. Since optical adjustment layers 72R, 72G, and 72B have different film thicknesses, it is possible to set an optical distance that causes optimum resonance for a wavelength of light according to the color to be displayed.

In the example illustrated in FIG. 17A, upper surfaces of the reflectors 71 in light emitting elements 12R, 12G, and 12B are disposed so as to be aligned. As described above, since the film thickness of the optical adjustment layer 72 is different according to the color to be displayed by the pixel, positions of upper surfaces of the second electrode 123 are different according to the type of the light emitting elements 12R, 12G, and 12B.

The reflectors 71 can include a metal such as aluminum (Al), silver (Ag), or copper (Cu), or an alloy containing these metals as principal components, for example.

The optical adjustment layer 72 can be constituted by an inorganic insulating material such as silicon nitride (SiNx), silicon oxide (SiOx), or silicon oxynitride (SiOxNy), or an organic resin material such as an acrylic resin or a polyimide resin. Each optical adjustment layer 72 may be a single layer, or may be a laminated film including a plurality of materials.

Furthermore, the number of stacked layers may be different according to the type of the light emitting element 12.

The first electrode 121 can be formed using a transparent conductive material such as indium tin oxide (ITO), indium zinc oxide (IZO), or zinc oxide (ZnO).

The second electrode 123 needs to function as a semi-transmission reflection film. The second electrode 123 can include magnesium (Mg), silver (Ag), a magnesium-silver alloy (MgAg) containing these materials as the principal components, an alloy containing an alkali metal or an alkaline earth metal, or the like.

### (Resonator Structure: Second Example)

FIG. 17B is a schematic cross-sectional view for explaining a second example of the resonator structure.

Also in the second example, the first electrode 121 and the second electrode 123 are formed to have a common film thickness in each light emitting element 12.

Then, also in the second example, the reflector 71 is disposed below the first electrode 121 of the light emitting element 12 with the optical adjustment layer 72 interposed therebetween. The resonator structure that causes resonance of light generated by the OLED layer 122 is formed between the reflector 71 and the second electrode 123. Similarly to the first example, the reflector 71 is formed to have a common film thickness in each light emitting element 12, and the film thickness of the optical adjustment layer 72 is different according to the color to be displayed by the pixel.

In the first example illustrated in FIG. 17A, upper surfaces of the reflectors 71 in the light emitting elements 12R, 12G, and 12B have been disposed so as to be aligned, and positions of the upper surfaces of the second electrodes 123 have been different according to the types of the light emitting elements 12R, 12G, and 12B.

On the other hand, in the second example illustrated in FIG. 17B, the upper surfaces of the second electrodes 123 are disposed so as to be aligned with the light emitting elements 12R, 12G, and 12B. In order to align the upper surfaces of the second electrodes 123, the upper surfaces of the reflectors 71 in the light emitting elements 12R, 12G, and 12B are disposed to be different according to the types of the light emitting elements 12R, 12G, and 12B. Therefore, the lower surface (in other words, the upper surface of the base layer (insulating layer) 73) of the reflector 71 has a stair shape according to the type of the light emitting element 12.

Materials and the like constituting the reflector 71, the optical adjustment layer 72, the first electrode 121, and the second electrode 123 are similar to those in contents described in the first example, and thus the description thereof is omitted.

### (Resonator Structure: Third Example)

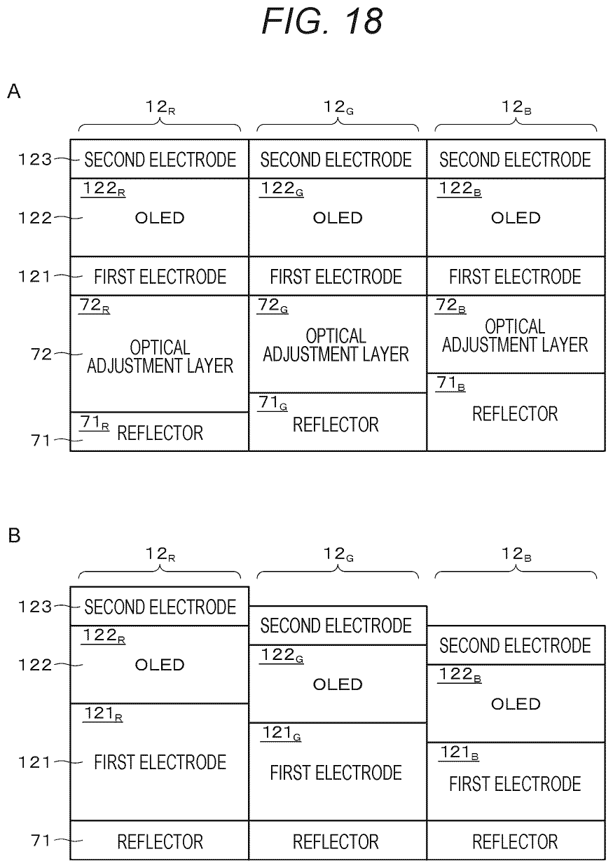

FIG. 18A is a schematic cross-sectional view for explaining a third example of the resonator structure. In the following description, the reflectors 71 provided corresponding to the sub-pixels 10R, 10G, and 10B may be referred to as reflectors 71R, 71G, and 71B, respectively.

Also in the third example, the first electrode 121 and the second electrode 123 are formed to have a common film thickness in each light emitting element 12.

Then, also in the third example, the reflector 71 is disposed below the first electrode 121 of the light emitting element 12 with the optical adjustment layer 72 interposed therebetween. The resonator structure that causes resonance of light generated by the OLED layer 122 is formed between the reflector 71 and the second electrode 123. Similarly to the first and the second examples, the film thickness of the optical adjustment layer 72 is different according to the color to be displayed by the pixel. Then, similarly to the second example, the light emitting elements 12R, 12G, and 12B are disposed such that positions of upper surfaces of the second electrodes 123 are aligned.

In the second example illustrated in b of FIG. 17B, in order to align the upper surfaces of the second electrodes 123, the lower surface of the reflector 71 has had a stair shape according to the type of the light emitting element 12.

On the other hand, in the third example illustrated in FIG. 18A, the film thickness of the reflector 71 is set to be different according to the types of the light emitting elements 12R, 12G, and 12B. More specifically, the film thickness is set such that lower surfaces of the reflectors 71R, 71G, and 71B are aligned.

Materials and the like constituting the reflector 71, the optical adjustment layer 72, the first electrode 121, and the second electrode 123 are similar to those in contents described in the first example, and thus the description thereof is omitted.

### (Resonator Structure: Fourth Example)

FIG. 18B is a schematic cross-sectional view for explaining a fourth example of the resonator structure. In the following description, the first electrodes 121 provided corresponding to the sub-pixels 10R, 10G, and 10B may be referred to as first electrodes 121R, 121G, and 121B, respectively.

In the first example illustrated in FIG. 17A, the first electrode 121 and the second electrode 123 of each light emitting element 12 is formed to have a common film thickness. Then, the reflector 71 is disposed below the first electrode 121 of the light emitting element 12 with the optical adjustment layer 72 interposed therebetween.

On the other hand, in the fourth example illustrated in FIG. 18B, the optical adjustment layer 72 is omitted, and the film thickness of the first electrode 121 is set to be different according to the types of the light emitting elements 12R, 12G, and 12B.

The reflector 71 is formed to have a common film thickness in each light emitting element 12. The film thickness of the first electrode 121 is different according to the color to be displayed by the pixel. Since first electrodes 121R, 121G, and 121B have different film thicknesses, it is possible to set an optical distance that causes optimum resonance for a wavelength of light according to the color to be displayed.

Materials and the like constituting the reflector 71, the optical adjustment layer 72, the first electrode 121, and the second electrode 123 are similar to those in contents described in the first example, and thus the description thereof is omitted.

### (Resonator Structure: Fifth Example)

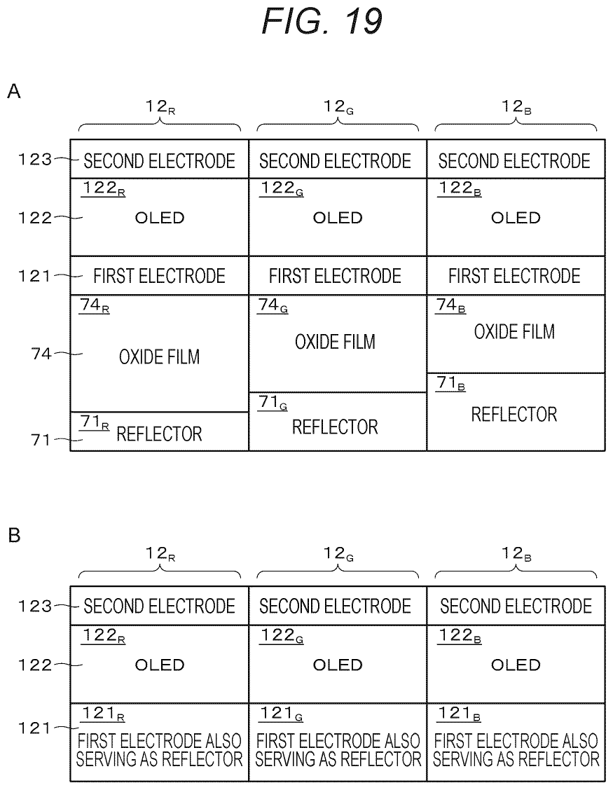

FIG. 19A is a schematic cross-sectional view for explaining a fifth example of the resonator structure.

In the first example illustrated in FIG. 17A, the first electrode 121 and the second electrode 123 are formed to have a common film thickness in each light emitting element 12. Then, the reflector 71 is disposed below the first electrode 121 of the light emitting element 12 with the optical adjustment layer 72 interposed therebetween.

On the other hand, in the fifth example illustrated in FIG. 19A, the optical adjustment layer 72 has been omitted, and instead, an oxide film 74 has been formed on a surface of the reflector 71. A film thickness of the oxide film 74 has been set to be different according to the types of the light emitting elements 12R, 12G, and 12B. In the following description, the oxide films 74 provided corresponding to the sub-pixels 10R, 10G, and 10B may be referred to as oxide films 74R, 74G, and 74B, respectively.

The film thickness of the oxide film 74 is different according to the color to be displayed by the pixel. Since oxide films 74R, 74G, and 74B have different film thicknesses, it is possible to set an optical distance that causes optimum resonance for a wavelength of light according to the color to be displayed.

The oxide films 74 are films obtained by oxidizing the surfaces of the reflectors 71, and include aluminum oxide, tantalum oxide, titanium oxide, magnesium oxide, zirconium oxide, or the like, for example. The oxide films 74 function as insulating films for adjusting the optical path lengths (optical distances) between the reflectors 71 and the second electrodes 123.

The oxide film 74 having different film thicknesses according to the types of the light emitting elements 12R, 12G, and 12B can be formed, for example, as follows.

First, an electrolytic solution is filled in the container, and a substrate on which the reflector 71 is formed is immersed in the electrolytic solution. Furthermore, an electrode is disposed so as to face the reflector 71.

Then, a positive voltage is applied to the reflector 71 with reference to the electrode, and the reflector 71 is anodized. A film thickness of the oxide film due to the anodization is proportional to a voltage value for the electrode. Therefore, anodization is performed in a state where a voltage according to the type of the light emitting element 12 is applied to each of the reflectors 71R, 71G, and 71B. As a result, the oxide films 74 having different film thicknesses can be collectively formed.

Materials and the like constituting the reflector 71, the first electrode 121, and the second electrode 123 are similar to those in contents described in the first example, and thus description thereof is omitted.

### (Resonator Structure: Sixth Example)

FIG. 19B is a schematic cross-sectional view for explaining a sixth example of the resonator structure.

In the sixth example, the light emitting element 12 is configured by stacking the first electrode 121, the OLED layer 122, and the second electrode 123. However, in the sixth example, the first electrode 121 is formed to function as both an electrode and a reflector. The first electrodes (also serving as reflectors) 121 include a material having an optical constant selected in accordance with the types of the light emitting elements 12R, 12G, and 12B. Since a phase shift by the first electrodes (also serving as reflectors) 121 vary, it is possible to set an optical distance that causes optimum resonance for a wavelength of light according to the color to be displayed.

The first electrodes (also serving as reflectors) 121 can include a single-component metal such as aluminum (Al), silver (Ag), gold (Au), or copper (Cu), or an alloy containing these metals as the principal components. For example, the first electrode (also serving as a reflector) 121R of the light emitting element 12R may be formed containing copper (Cu), and the first electrode (also serving as a reflector) 121G of the light emitting unit 12G and the first electrode (also serving as a reflector) 121B of the light emitting element 12B may be formed containing aluminum.

Materials and the like constituting the second electrode 123 are similar to those in contents described in the first example, and thus the description thereof will be omitted.

### (Resonator Structure: Seventh Example)

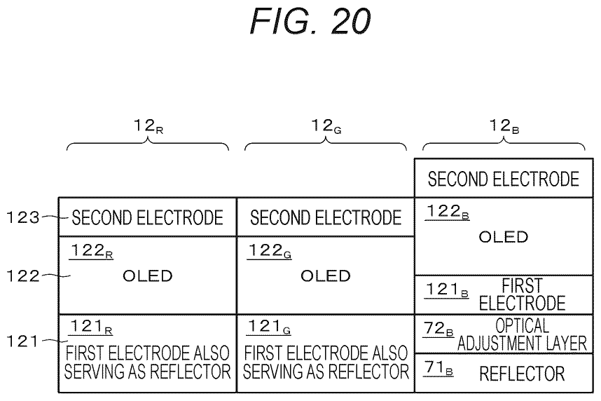

FIG. 20 is a schematic cross-sectional view for explaining a seventh example of the resonator structure.

In the seventh example, basically, the sixth example is applied to the light emitting elements 12R and 12G, and the first example is applied to the light emitting element 12B. Also in this configuration, it is possible to set an optical distance that causes optimum resonance for a wavelength of light according to the color to be displayed.

The first electrodes (also serving as reflectors) 121R and 121G used for the light emitting elements 12R and 12G can be formed containing a single metal such as aluminum (Al), silver (Ag), gold (Au), or copper (Cu), or an alloy containing these as a main component.

Materials and the like constituting the reflector 71B, the optical adjustment layer 72B, and the first electrode 121B used for the light emitting element 12B are similar to those in contents described in the first example, and thus description thereof is omitted.

### 6 APPLICATION EXAMPLE

### (Electronic Apparatuses)

The display devices 101, 102, 103, 104, 105, and 106 (hereinafter, referred to as “display device 101 and the like”) according to the above one embodiment and the modifications thereof described above can be included in various types of electronic apparatuses. The display device 101 and the like are particularly required to have high resolution such as an eyewear device such as a head-mounted display or an electronic viewfinder of a video camera or a single-lens reflex camera, and are suitable for those that are enlarged and used near the eyes.

### Specific Example 1

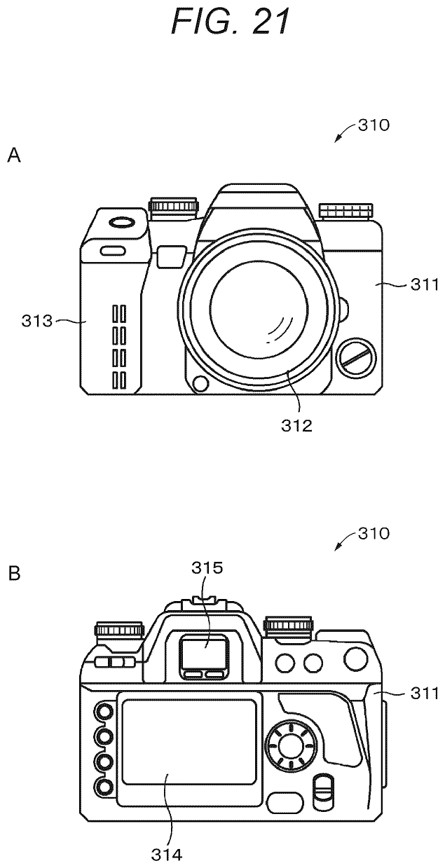

FIG. 21A and FIG. 21B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic viewfinder (eyepiece window) 315 is provided above the monitor 314. By looking through the electronic view finder 315, the photographer can visually recognize an optical image of the subject guided from the imaging lens unit 312, and determine a picture composition. The electronic view finder 315 includes any of the above display device 101 and the like.

### Specific Example 2

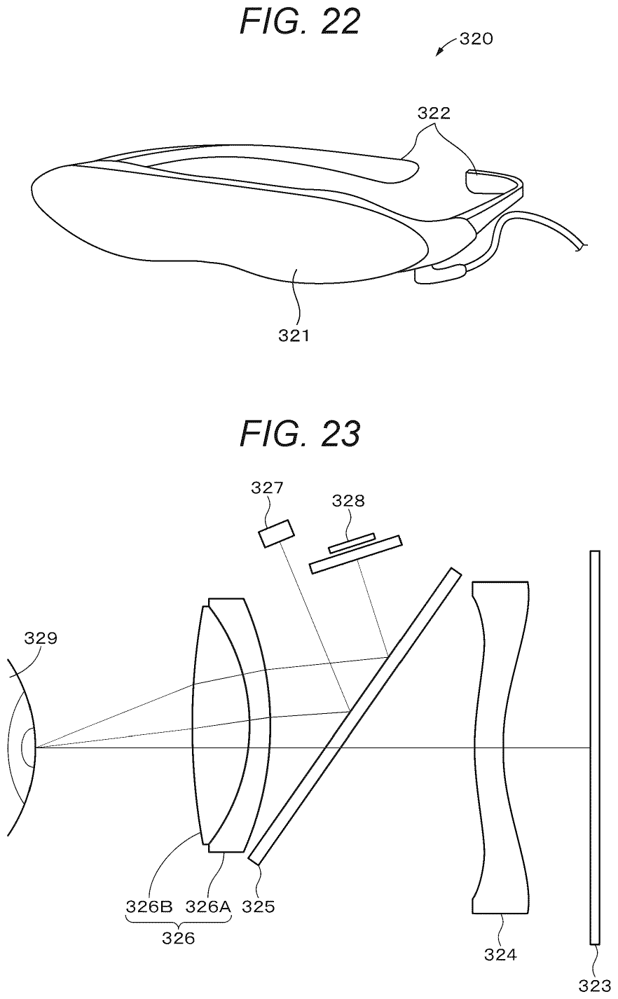

FIG. 22 illustrates an example of an external appearance of a head-mounted display 320. The head-mounted display 320 is an example of an eyewear device. The head-mounted display 320 includes ear hooking portions 322 to be worn on the head of the user on both sides of a display unit 321 in the shape of eyeglasses, for example. The display unit 321 includes any one of the above display device 101 and the like.

FIG. 23 illustrates an example of a configuration of the head-mounted display 320. The head-mounted display 320 includes a screen 323, a lens 324, a hot mirror 325, a lens group 326, a light emitting element 327, and an imaging element 328.

The screen 323 includes any one of the above display devices 101 and the like. The lens 324 is provided between the screen 323 and the hot mirror 325. The lens 324 adjusts an optical path of image light emitted from the screen 323. The hot mirror 325 is provided between the lens 324 and the lens group 326. The hot mirror 325 transmits visible light but reflects near infrared rays. Specifically, the hot mirror 325 transmits image light (visible light) emitted from the screen 323, and reflects near infrared rays emitted from the light emitting element 327 and near infrared rays reflected by the eye 329.

The lens group 326 can be positioned between the hot mirror 325 and the eye 329 in a state where the head-mounted display 320 is worn by the user. The lens group 326 includes a concave lens 326A and a convex lens 326B. The concave lens 326A and the convex lens 326B are cemented. The concave lens 326A is provided on the front side as viewed from the screen 323, and the convex lens 326B is provided on the back side as viewed from the screen 323.

The light emitting element 327 can emit near infrared rays. The light emitting element 327 is, for example, an LED element. The near infrared ray emitted from the light emitting element 327 is reflected by the hot mirror 325 and enters the eye 329.

The imaging element 328 is an imaging element for eye tracking, and can image near infrared rays reflected by the eye 329.

As the eye tracking of the head-mounted display 320, for example, a pupil center cornea reflection (PCCR) method is used. In the pupil center cornea reflection method, a reflection point of light is generated on the cornea, and the image is captured by the imaging element 328. The reflection point of the light on the cornea and the pupil are identified from the captured image of the eyeball. The direction of the eyeball is calculated on the basis of the reflection point of light and other geometric features. A reflection pattern generated on the cornea by near infrared rays from the light emitting element 327 is acquired by the imaging element 328. Advanced image processing algorithms and physiological 3D models of the eyeball can be used to estimate the position and viewpoint of the eye in space with high accuracy.

The head-mounted display 320 of Specific Example 2 includes any one of the display devices 101 and the like as the screen 323. Therefore, this makes it possible to suppress the generation of stray light of near infrared rays. Accordingly, image noise due to stray light of near infrared rays can be suppressed.

### Specific Example 3

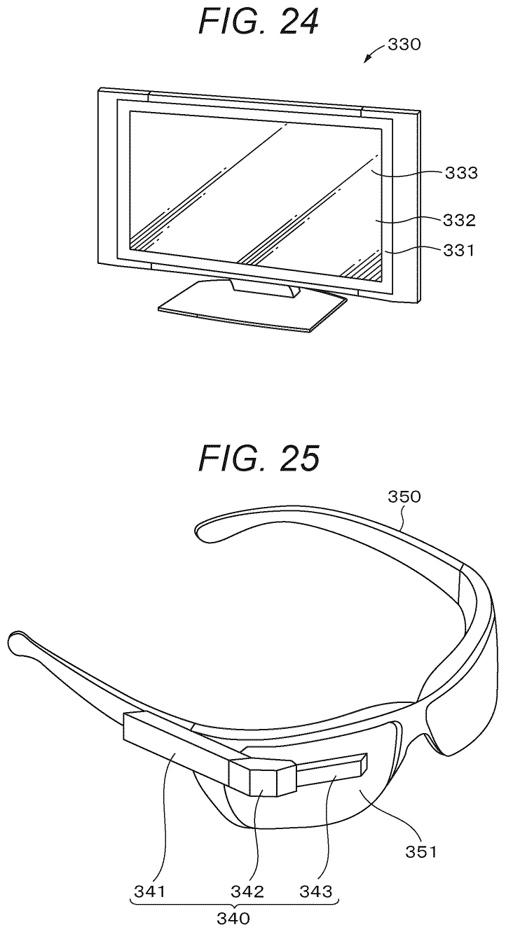

FIG. 24 illustrates an example of an external appearance of a television device 330. The television device 330 includes, for example, a video display screen unit 331 including a front panel 332 and a filter glass 333, and a video display screen unit 331 includes any one of the above display device 101 and the like.

### Specific Example 4

FIG. 25 illustrates an example of an external appearance of a see-through head-mounted display 340. The see-through head-mounted display 340 is an example of an eyewear device. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be directly mounted on the head of the human body.

The main body 341 incorporates a control board for controlling operation of the see-through head-mounted display 340, and a display unit. The arm 342 connects the main body 341 and the lens barrel 343, and supports the lens barrel 343.

Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 via the arm 342 toward the eyes of the user wearing the see-through head-mounted display 340 through an eyeglass 351. In this see-through head-mounted display 340, the display unit of the main body 341 includes one of the above display device 101 and the like.

### Specific Example 5

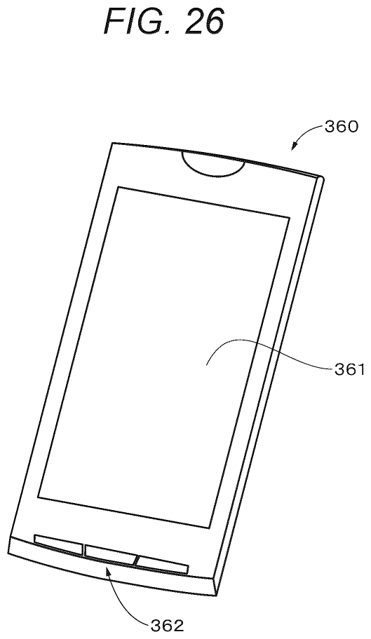

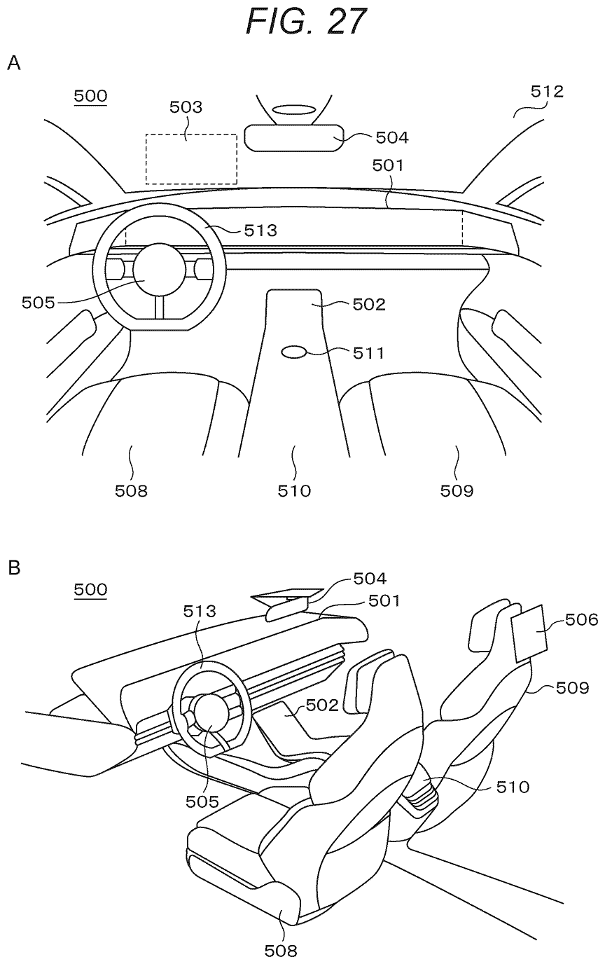

FIG. 26 illustrates an example of an external appearance of a smartphone 360. The smartphone 360 includes a display unit 361 for displaying various types of information, an operation unit 362 including a button for receiving an operation input by the user, and the like. The display unit 361 includes any one of the above display devices 101 and the like.

### Specific Example 6

The display device 101 and the like may be provided in various displays provided in the vehicle.

FIGS. 27A and 27B are diagrams illustrating an example of an internal configuration of a vehicle 500 provided with various types of displays. Specifically, FIG. 27A is a diagram illustrating an example of an internal state of the vehicle 500 as viewed from the rear side to the front side of the vehicle 500. FIG. 27B is a diagram illustrating an example of an internal state of the vehicle 500 as viewed from the oblique rear side to the oblique front side of the vehicle 500.

The vehicle 500 includes a center display 501, a console display 502, a head-up display 503, a digital rearview mirror 504, a steering wheel display 505, and a rear entertainment display 506. At least one of these displays includes any one of the above display device 101 and the like. For example, all of these displays may include one of the above display device 101 and the like.

The center display 501 is disposed on the dashboard at a location facing a driver's seat 508 and a passenger seat 509. FIGS. 27A and 27B illustrate an example of the center display 501 having a horizontally long shape extending from the side of the driver's seat 508 to the side of the passenger seat 509, but any screen size and installation location for the center display 501 may be adopted. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, and the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information senses a gesture related to an operation performed by an occupant, using a sensor. Gestures to be sensed may include an operation of various kinds of equipment in the vehicle 500. For example, operations of air conditioning equipment, a navigation device, an audiovisual (AV) device, an illuminating device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged with an image sensor, and the health condition of the occupant may be estimated from the imaged facial expression.

Moreover, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back side of the driver's seat 508 or the passenger seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, as the rear entertainment display 506 is located in front of an occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

A sensor may be disposed on the back surface side of a display device 101 and the like in an overlapping manner, so that the distance to an object present in the surroundings can be measured in the configuration. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the display devices 101 and the like described above can be used in distance measurement by any of these methods. With a sensor disposed on the back surface side of the above display device 101 and the like in an overlapping manner, distance measurement of the passive type or the active type described above can be performed.

### REFERENCE SIGNS LIST

10Px Pixel
10R, 10G, 10B Sub-pixel
11 Drive board
111 Substrate
112 Insulating layer
113 Guard ring
12W Light emitting element
13 Insulating layer
14 Protective layer
15 Protective layer
16 Planarization layer
17 Color filter
17FR Red filter portion
17FG Green filter portion 17FB Blue filter portion
17BK Light shielding layer
18 Near-infrared absorption layer
181 Pattern portion
181M Near-infrared absorption portion
181N Opening portion
182 Non-pattern portion
19 Protective layer
20 Cover glass
21 Planarization layer
22 Lens array
221 Lens
23 Reflection suppressing layer
101, 102, 103, 104, 105 Display device
310 Digital still camera
320 Head-mounted display
330 Television device
340 See-through head-mounted display
360 Smartphone
500 Vehicle
RE1 Effective pixel region
RE2 Peripheral region

1. A light emitting device comprising:
a near-infrared absorption layer, wherein
the near-infrared absorption layer is provided in an effective pixel region and a peripheral region located around the effective pixel region, and
the near-infrared absorption layer includes a pattern portion in the effective pixel region.

2. The light emitting device according to claim 1, wherein
the near-infrared absorption layer includes a non-pattern portion in the peripheral region.

3. The light emitting device according to claim 1, wherein
the pattern portion has a plurality of opening portions,
the plurality of opening portions is two-dimensionally arranged, and
each of the opening portions is provided in units of sub-pixels or pixels.

4. The light emitting device according to claim 1, further comprising:
a color filter, wherein
the color filter includes a filter portion of a plurality of colors,
the pattern portion has a plurality of openings, and
each of the opening portions is provided at a position of at least one of the filter portions of the plurality of colors.

5. The light emitting device according to claim 1, further comprising:
a color filter, wherein
the color filter includes a red filter portion, a green filter portion, and a blue filter portion,
the pattern portion has a plurality of opening portions, and
each of the opening portions is provided at a position of the red filter portion.

6. The light emitting device according to claim 1, further comprising:
a color filter, wherein
the color filter includes a red filter portion, a green filter portion, and a blue filter portion,
the pattern portion has a plurality of opening portions, and
the opening portions each are provided at positions of the red filter portion and the green filter portion.

7. The light emitting device according to claim 1, further comprising:
a color filter, wherein
the pattern portion is provided on the color filter or above the color filter.

8. The light emitting device according to claim 2, further comprising:
a light shielding layer, wherein
the light shielding layer is provided in the peripheral region, and
the non-pattern portion is provided on the light shielding layer or above the light shielding layer.

9. The light emitting device according to claim 2, further comprising:
a light shielding layer; and
a protective layer, wherein
the light shielding layer is provided in the peripheral region,
the protective layer covers the pattern portion and the light shielding layer, and
the non-pattern portion is provided on the protective layer.

10. The light emitting device according to claim 1, wherein
the near-infrared absorption layer includes a photoresist and a near-infrared absorption material.

11. The light emitting device according to claim 1, further comprising:
a cover glass, wherein
the near-infrared absorption layer is provided inside the cover glass.

12. The light emitting device according to claim 1, further comprising:
a reflection suppressing layer capable of suppressing visible light reflection.

13. An eyewear device comprising:
the light emitting device according to claim 1.
